(19) United States
(12) Patent Application Publication
(10) Pub. No.: US 2025/0240979 A1
(43) Pub. Date: Jul. 24, 2025

(54) MEMORY DEVICE

(71) Applicant: Samsung Electronics Co., Ltd., Suwon-si (KR)

(72) Inventors: Kohji KANAMORI, Suwon-si (KR); Seunghyun LEE, Suwon-si (KR); Seogoo KANG, Suwon-si (KR); Junghoon JUN, Suwon-si (KR); Jeehoon HAN, Suwon-si (KR)

(73) Assignee: Samsung Electronics Co., Ltd., Suwon-si (KR)

(21) Appl. No.: 18/811,982

(22) Filed: Aug. 22, 2024

(30) Foreign Application Priority Data
Jan. 23, 2024 (KR) 10-2024-0010402

(51) Int. Cl. H10B 80/00; H01L 23/00; H01L 25/00; H01L 25/065; H01L 25/18; H10B 41/27; H10B 43/27

(52) U.S. Cl. CPC H10B 80/00; H01L 24/08; H01L 24/80; H01L 25/0657; H01L 25/18; H01L 25/50; H10B 41/27; H10B 43/27; H01L 2224/08145; H01L 2224/80006; H01L 2224/80895; H01L 2224/80896; H01L 2924/1431; H01L 2924/14511

(57) ABSTRACT

Provided are a memory device and a method of manufacturing the same. The memory device includes a peripheral stack including a plurality of circuits, a lower cell array stack including a gate stack including a plurality of gate lines, a gate line contact passing through at least a part of the gate stack and electrically connected to a gate line selected from among the plurality of gate lines, a plurality of through-vias passing through the gate stack and connected to corresponding ones of the plurality of circuits of the peripheral circuit stack, and a wiring structure connecting one of the plurality of through-vias to the gate line contact.

### CROSS-REFERENCE TO RELATED APPLICATION

This application and claims priority under 35 U.S.C. § 119 to Korean Patent Application No. 10-2024-0010402, filed on Jan. 23, 2024, in the Korean Intellectual Property Office, the disclosure of which is incorporated by reference herein in its entirety.

### BACKGROUND

The inventive concepts relate to memory devices, and more particularly, to memory devices including a nonvolatile vertical memory element.

In an electronic system requiring data storage, a memory device capable of storing high-volume data is required. Accordingly, to increase a data storage capacity of a memory device, a memory device including a vertical memory element including three-dimensionally arranged memory cells has been proposed.

### SUMMARY

The inventive concepts provide a memory devices having three-dimensionally arranged memory cells and relatively improved integration and reliability.

Technical problems to be solved by the inventive concepts are not limited to the above-described technical problems and one of ordinary skill in the art will understand other technical problems from the following description.

According to an example embodiment of the inventive concepts, a memory device includes a peripheral circuit stack including a circuit board and a plurality of circuits on the circuit board, a lower cell array stack including a first gate stack on the peripheral circuit stack, the first gate stack including a plurality of first gate lines stacked in a vertical direction, a first vertical channel structure passing through the first gate stack, a first gate line contact passing through at least a part of the first gate stack, the first gate line contact electrically connected to a first gate line selected from among the plurality of first gate lines, a plurality of first through-vias spaced apart from the first gate line contact in a horizontal direction and passing through the first gate stack, the plurality of first through-vias connected to corresponding ones of the plurality of circuits of the peripheral circuit stack, and a first wiring structure configured to electrically connect at least one of the plurality of first through-vias to the first gate line contact, wherein the plurality of first through-vias include a first vertical interconnect and a second vertical interconnect, wherein the first vertical interconnect is electrically connected to the first gate line contact through the first wiring structure, and the second vertical interconnect is not electrically connected to the first wiring structure.

According to an example embodiment of the inventive concepts, a memory device includes a peripheral circuit stack including a circuit board and a plurality of circuits on the circuit board, a lower cell array stack including a first gate stack on the peripheral circuit stack, the first gate stack including a plurality of first gate lines stacked in a vertical direction, a first vertical channel structure passing through the first gate stack, a first gate line contact passing through at least a part of the first gate stack to be electrically connected to a first gate line selected from among the plurality of first gate lines, a plurality of first through-vias spaced apart from the first gate line contact in a horizontal direction, the plurality of first through-vias connected to the plurality of circuits of the peripheral circuit stack, respectively, and plurality of first through-vias partially overlapping a part of the first gate line contact in the vertical direction, a first wiring structure configured to electrically connect at least one of the plurality of first through-vias to the first gate line contact, a first bit line overlapping the first vertical channel structure in the vertical direction, and a first common source line spaced apart from the first bit line in the vertical direction with the first vertical channel structure therebetween.

According to an example embodiment of the inventive concepts, a memory device includes a peripheral circuit stack including a circuit board and a plurality of circuits on the circuit board, a lower cell array stack including a first gate stack on the peripheral circuit stack, the first gate stack including a plurality of first gate lines, the plurality of first gate lines being parallel to each other in a horizontal direction and overlapping each other in a vertical direction, a first vertical channel structure passing through the first gate stack, a first gate line contact passing through at least a part of the first gate stack and electrically connected to a first gate line selected from among the plurality of first gate lines, a plurality of first through-vias spaced apart from the first gate line contact in the horizontal direction, the plurality of first through-vias passing through the first gate stack and connected to corresponding ones of the plurality of circuits of the peripheral circuit stack, a first wiring structure configured to electrically connect at least one of the plurality of first through-vias to the first gate line contact, a first bit line between the first vertical channel structure and the peripheral circuit stack, the first bit line electrically connected to the first vertical channel structure, and a first common source line spaced apart from the peripheral circuit stack with the first vertical channel structure therebetween, the first common source line configured to supply a common source voltage or a ground voltage to the first vertical channel structure, and an upper cell array stack on the lower cell array stack, the upper cell array stack including a second gate stack including a plurality of second gate lines, the plurality of second gate lines being parallel to each other in the horizontal direction and overlapping each other in the vertical direction, a second vertical channel structure passing through the second gate stack, a second gate line contact passing through at least a part of the second gate stack and electrically connected to a second gate line selected from among the plurality of second gate lines, a plurality of second through-vias passing through the second gate stack and spaced apart from the second gate line contact in the horizontal direction, a second wiring structure configured to electrically connect at least one of the plurality of second through-vias to the second gate line contact, a second bit line spaced apart from the lower cell array stack with the second vertical channel structure therebetween and electrically connected to the second vertical channel structure, and a second common source line between the second vertical channel structure and the lower cell array stack, the second common source line configured to supply a common source voltage or a ground voltage to the second vertical channel structure, wherein each of the plurality of first through-vias and the plurality of second through-vias includes a first vertical interconnect and a second vertical interconnect, wherein the first vertical interconnect from among the plurality of first through-vias is electrically connected to the first gate line contact through the first wiring structure, and the first vertical interconnect from among the plurality of second through-vias is electrically connected to the second gate line contact through the second wiring structure, and the second vertical interconnect is not electrically connected to any one of the first wiring structure and the second wiring structure.

### BRIEF DESCRIPTION OF THE DRAWINGS

Example embodiments will be more clearly understood from the following detailed description taken in conjunction with the accompanying drawings in which:

FIG. 1 is a block diagram illustrating a memory device, according to an example embodiment;

FIG. 2 is a circuit diagram illustrating a memory block, according to an example embodiment;

FIG. 3A is a perspective view illustrating a representative configuration of a memory device, according to an example embodiment;

FIG. 3B is a view for describing a memory device, according to an example embodiment;

FIG. 4 is a plan layout view illustrating an area “A” in FIG. 3A;

FIG. 5A is an enlarged view illustrating an example of an area “EX1” of FIG. 4;

FIG. 5B is an enlarged view illustrating another example of the area “EX1” of FIG. 4;

FIG. 6 is a cross-sectional view taken along a line A1-A1′ of FIG. 4;

FIG. 7A is a cross-sectional view taken along a line A2-A2′ of FIG. 4;

FIG. 7B is an enlarged view illustrating an area “EX2” of FIG. 7A;

FIG. 8 is a cross-sectional view taken along a line B1-B1′ of FIG. 4;

FIGS. 9 to 24 are cross-sectional views sequentially illustrating a process order of a manufacturing method, according to an example embodiment;

FIG. 25 is a view for describing a memory device, according to an example embodiment

FIG. 26A is a view for describing a memory device, according to an example embodiment;

FIG. 26B is an enlarged view illustrating an area “EX3” of FIG. 26A;

FIG. 27 is a view schematically illustrating a data storage system including a memory device, according to an example embodiment;

FIG. 28 is a perspective view schematically illustrating a data storage system including a semiconductor device, according to an example embodiment; and

FIG. 29 is a cross-sectional view schematically illustrating semiconductor packages, according to an example embodiment.

### DETAILED DESCRIPTION

Hereinafter, some example embodiments will be described in detail with reference to the accompanying drawings. The same elements are denoted by the same reference numerals in the drawings, and thus, a repeated description thereof will be omitted.

In the specification, a horizontal direction may include a first horizontal direction (X direction) and a second horizontal direction (Y direction) intersecting each other. A direction intersecting the first horizontal direction (X direction) and the second direction (Y direction) may be referred to as a vertical direction (Z direction). In the specification, a vertical level may be referred to as a height level along the vertical direction (Z direction) of any configuration.

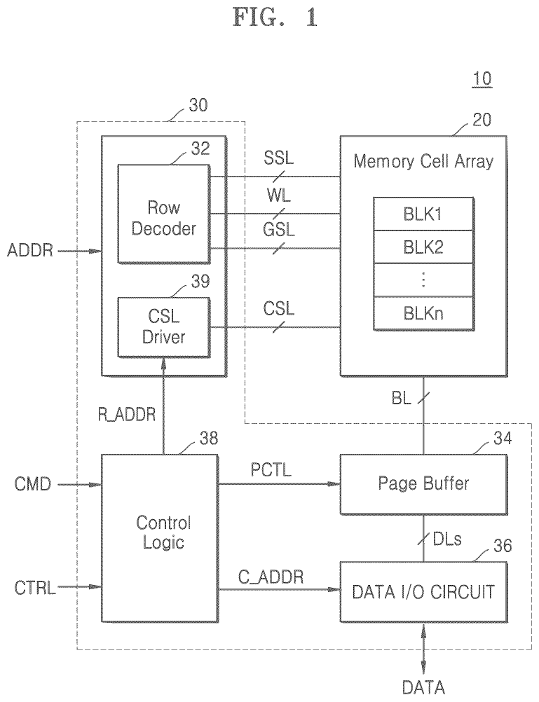

FIG. 1 is a block diagram illustrating a memory device 10, according to an example embodiment.

Referring to FIG. 1, the memory device 10 may include a memory cell array 20 and a peripheral circuit 30. The memory cell array 20 includes a plurality of memory cell blocks BLK1, BLK2, . . . , and BLKn. Each of the plurality of memory cell blocks BLK1, BLK2, . . . , and BLKn may include a plurality of memory cells. The memory cell blocks BLK1, BLK2, . . . , and BLKn may be connected to the peripheral circuit 30 through a bit line BL, a word line WL, a string selection line SSL, and a ground selection line GSL.

The peripheral circuit 30 may include a row decoder 32, a page buffer 34, a data input/output circuit 36, a control logic 38, and a common source line driver 39. Although not shown in FIG. 1, the peripheral circuit 30 may further include an input/output interface, a column logic, a voltage generator, a pre-decoder, a temperature sensor, a command decoder, an address decoder, and/or an amplification circuit.

The memory cell array 20 may be connected to the page buffer 34 through the bit line BL, and may be connected to the row decoder 32 through the word line WL, the string selection line SSL, and the ground selection line GSL. In the memory cell array 20, each of the plurality of memory cells included in the plurality of memory cell blocks BLK1, BLK2, . . . , and BLKn may be a flash memory cell. The memory cell array 20 may include a three-dimensional (3D) memory cell array. The 3D memory cell array may include a plurality of NAND strings, and each NAND string may include a plurality of memory cells connected to a plurality of word lines WL stacked vertically on a substrate.

The peripheral circuit 30 may receive an address ADDR, a command CMD, and a control signal CTRL from the outside of the memory device 10 and may transmit and receive data DATA to and from a device outside the memory device 10.

The row decoder 32 may select at least one of the plurality of memory cell blocks BLK1, BLK2, . . . , or BLKn in response to the address ADDR from the outside and may select the word line WL, the string selection line SSL, and the ground selection line GSL of the selected memory cell block. The row decoder 32 may transmit a voltage for performing a memory operation to the word line WL of the selected memory cell block.

The page buffer 34 may be connected to the memory cell array 20 through the bit line BL. The page buffer 34 may operate as a write driver during a program operation to apply a voltage according to the data DATA to be stored in the memory cell array 20 to the bit line BL, and may operate as a sense amplifier during a read operation to detect the data DATA stored in the memory cell array 20. The page buffer 34 may operate according to a control signal PCTL provided from the control logic 38.

The data input/output circuit 36 may be connected to the page buffer 34 through data lines DLs. During a program operation, the data input/output circuit 36 may receive the data DATA from a memory controller (not shown) and may provide program data DATA to the page buffer 34 based on a column address C_ADDR provided from the control logic 38. During a read operation, the data input/output circuit 36 may provide, to the memory controller, read data DATA stored in the page buffer 34 based on the column address C_ADDR provided from the control logic 38.

The data input/output circuit 36 may transmit an input address or an instruction to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and may provide the column address C_ADDR to the data input/output circuit 36. The control logic 38 may generate various internal control signals used in the memory device 10 in response to the control signal CTRL. For example, the control logic 38 may adjust a level of a voltage provided to the word line WL and the bit line BL during a memory operation such as a program operation or an erase operation.

The common source line driver 39 may be connected to the memory cell array 20 through a common source line CSL. The common source line driver 39 may apply a common source voltage (e.g., a power supply voltage) or a ground voltage to the common source line CSL under the control of the control logic 38.

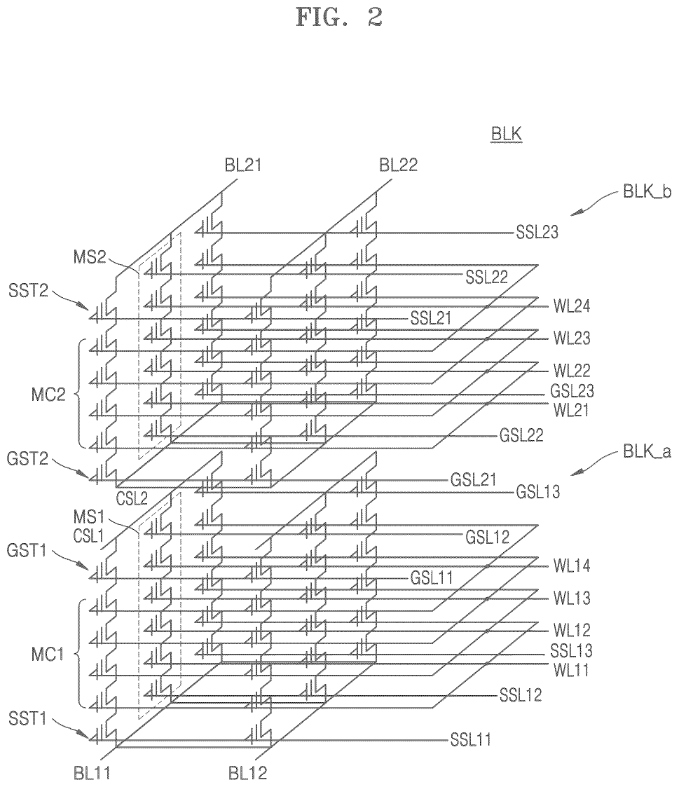

FIG. 2 is a circuit diagram illustrating a memory block BLK, according to an example embodiment.

Referring to FIG. 2, the memory block BLK may correspond to one of the plurality of memory blocks BLK1 to BLKn in FIG. 1. The memory block BLK may include a first sub-block BLK_a and a second sub-block BLK_b located at different vertical levels and vertically overlapping each other. The first sub-block BLK_a may include first NAND strings MS1, and the second sub-block BLK_b may include second NAND strings MS2.

The first NAND string MS1 may include a first string selection transistor SST1, a plurality of first memory cells MC1, and a first ground selection transistor GST1 which are connected in series. The second NAND string MS2 may include a second string selection transistor SST2, a plurality of second memory cells MC2, and a second ground selection transistor GST2 which are connected in series. The transistors (e.g., SST1 and GST1) and the first memory cells MC1 included in the first NAND string MS1 may form a structure stacked in a vertical direction on a substrate, and the transistors (e.g., SST2 and GST2) and the second memory cells MC2 included in the second NAND string MS2 may form a structure stacked in the vertical direction on the substrate.

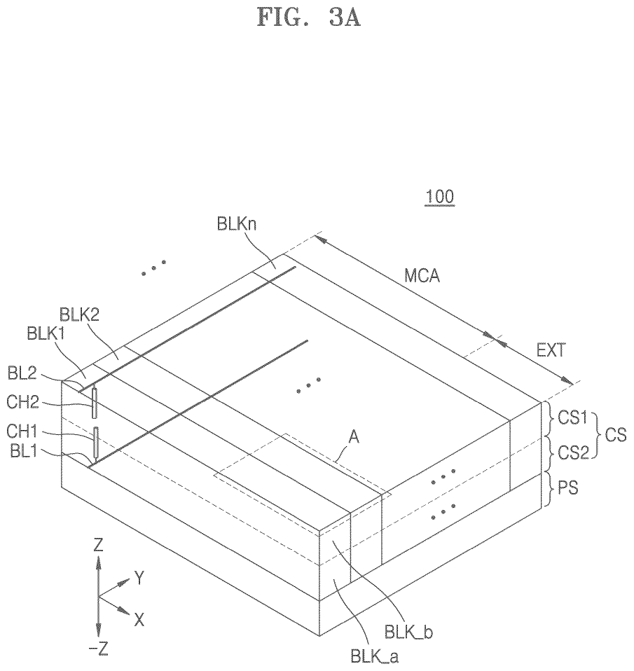

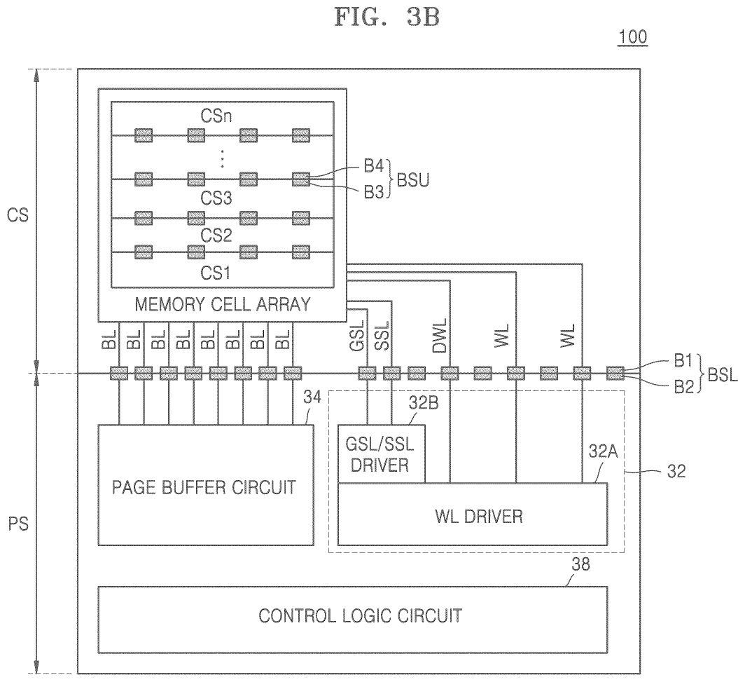

At a lower end of the first NAND string MS1, first bit lines BL11 and BL12 may extend along a first direction (e.g., Y direction of FIG. 3), and first word lines WL11, WL12, WL13, and WL14 may extend along a second direction (e.g., X direction of FIG. 3). The first NAND strings MS1 may be located between the first bit line BL1 and a first common source line CSL1. The first string selection transistor SST1 may be connected to corresponding first string selection lines SSL11, SSL12, and SSL13. The first memory cells MC1 may be connected to the corresponding first word lines WL11, WL12, WL13, and WL14, respectively. The first ground selection transistor GST1 may be connected to corresponding first ground selection lines GSL11, GSL12, and GSL13. The first string selection transistor SST1 may be connected to a corresponding bit line, and the first ground selection transistor GST1 may be connected to the first common source line CSL1.

At an upper end of the second NAND string MS2, second bit lines BL21 and BL22 may extend along the first direction (e.g., Y direction of FIG. 3), and second word lines WL21, WL22, WL23, and WL24 may extend along the second direction (e.g., X direction of FIG. 3). The second NAND strings MS2 may be located between the second bit line BL2 and a second common source line CSL2. The second string selection transistor SST2 may be connected to corresponding second string selection lines SSL21, SSL22, and SSL23. The second memory cells MC2 may be connected to the corresponding second word lines WL21, WL22, WL23, and WL2,4 respectively. The second ground selection transistor GST2 may be connected to corresponding second ground selection lines GSL21, GSL22, and GSL23. The second string selection transistor SST2 may be connected to a corresponding bit line, and the second ground selection transistor GST2 may be connected to the second common source line CSL2.

The number of NAND strings, the number of word lines, the number of bit lines, the number of ground selection lines, and the number of string selection lines may be changed in various ways according to example embodiments.

In some example embodiments, the same voltage may be applied to the first word lines WL11, WL12, WL13, and WL14 and the second word lines WL21, WL22, WL23, and WL24 respectively corresponding to the first word lines WL11, WL12, WL13, WL14. For example, the first word line WL11 that is a lowermost first word line and the second word line WL21 that is a lowermost second word line may be electrically connected to one word line driving circuit (e.g., a pass transistor), and the same voltage may be applied to the first word line WL11 that is a lowermost first word line and the second word line WL21 that is a lowermost second word line. Likewise, the first word line WL14 that is an uppermost first word line and the second word line WL24 that is an uppermost second word line may be electrically connected to one word line driving circuit (e.g., a pass transistor), and the same voltage may be applied to the first word line WL14 that is an uppermost first word line and the second word line WL24 that is an uppermost second word line.

In some example embodiments, the same voltage may be applied to the first string selection lines SSL11, SSL12, and SSL13 and the second string selection lines SSL21, SSL22, and SSL23 respectively corresponding to the first string selection lines SSL11, SSL12, and SSL13. For example, the first string selection line SSL11 that is located on the left and the second string selection line SSL21 that is located on the left may be electrically connected to one string selection line driving circuit, and the same voltage may be applied to the first string selection line SSL11 that is located on the left and the second string selection line SSL21 that is located on the left.

In some example embodiments, each of the first bit lines BL11 and BL12 may be configured to apply a voltage to the first NAND string MS1 from a first page buffer circuit, and each of the second bit lines BL21 and BL22 may be configured to apply a voltage to the second NAND string MS2 from a second page buffer circuit.

In some example embodiments, while the same word line voltage as the second memory cell MC2 connected to the second word line WL21 that is a lowermost second word line in the second NAND string MS2 may be applied to the first memory cell MC1 connected to the first word line WL11 that is a lowermost first word line in the first NAND string MS1, a bit line voltage applied to the first memory cell MC1 through the first bit line BL11 may be independent of a bit line voltage applied to the second memory cell MC2 through the second bit line BL21. Accordingly, the first memory cell MC1 may be read, programmed, or erased independently from the second memory cell MC2. In some other example embodiments, a bit line voltage applied to the first memory cell MC1 through the first bit line BL11 may be applied to the second memory cell MC2 through arbitrary conductive elements. The first memory cell MC1 may be simultaneously read, programmed, or erased with the second memory cell MC2.

FIG. 3A is a perspective view illustrating a representative configuration of a memory device 100, according to an example embodiment.

Referring to FIG. 3A, the memory device 100 includes a cell array stack CS and a peripheral circuit stack PS overlapping each other in the vertical direction (Z direction). The cell array stack CS may include the memory cell array 20 described with reference to FIG. 1, and the peripheral circuit stack PS may include the peripheral circuit 30 described with reference to FIG. 1.

The cell array stack CS may include a plurality of memory cell blocks BLK1, BLK2, . . . , and BLKn. Each of the plurality of memory cell blocks BLK1, BLK2, . . . , and BLKn may include memory cells that are three-dimensionally arranged. Each of the plurality of memory cell blocks BLK1, BLK2, . . . , and BLKn may include a first sub-block BLK_a and a second sub-block BLK_b overlapping each other in the vertical direction (Z direction) on the peripheral circuit stack PS. The first sub-block BLK_a may include a first vertical channel structure CH1 and a first bit line BL1 connected to the first vertical channel structure CH1, and the second sub-block BLK_b may include a second vertical channel structure CH2 located at a position overlapping the first vertical channel structure CH1 and a second bit line BL2 connected to the second vertical channel structure CH2.

The cell array stack CS may include a memory cell area MCR and an extension area EXT. The memory cell area MCR may be an area where the memory cell array 20 described with reference to FIG. 1 is located, and the extension area EXT may be an area where an electrical connection component, for example, a pad unit and/or a contact, for the word line WL of each memory cell array 20 is located.

In some example embodiments, the cell array stack CS may include a first cell array stack CS1 and a second cell array stack CS2 overlapping each other on the peripheral circuit stack PS. The first sub-block BLK_a may be located in the first cell array stack CS1, and the second sub-block BLK_b may be located in the second cell array stack CS2.

As shown in FIG. 3A, the first cell array stack CS1 may be located on the peripheral circuit stack PS, and the second cell array stack CS2 may be located on the first cell array stack CS1. In this case, in the first cell array stack CS1, the first bit line BL1 may be located on the peripheral circuit stack PS and the first channel structure CH1 may be located on the first bit line BL1, and in the second cell array stack CS2, the second channel structure CH2 may be located on the first cell array stack CS1 and the second bit line BL2 may be located on the second channel structure CH2.

FIG. 3B is a view for describing the memory device 100, according to an example embodiment. In FIG. 3B, the same members as those in FIGS. 1, 2, and 3A are denoted by the same reference numerals, and thus, a detailed description thereof will be omitted.

Referring to FIG. 3B, the memory device 100 may include the peripheral circuit stack PS and the cell array stack CS located on the peripheral circuit stack PS. There may be a plurality of cell array stacks CS, and the memory device 100 may include cell array stacks CS1, CS2, . . . , and CSn. However, this is only an example, and the memory device 100 may include the first cell array stack CS1 and the second cell array stack CS2 shown in FIG. 3A. The cell array stack CS may include the memory cell array 20 described with reference to FIG. 1, and the peripheral circuit stack PS may include the peripheral circuit 30 described with reference to FIG. 1.

Each of the plurality of cell array stacks CS1, CS2, . . . , and CSn may include a plurality of bit lines BL, a ground selection line GSL, a string selection line SSL, a plurality of word lines WL, and a dummy word line DWL. Each of the plurality of cell array stacks CS1, CS2, . . . , and CSn may include a plurality of first bonding pads B1 respectively connected to the plurality of bit lines BL, the ground selection line GSL, the string selection line SSL, the plurality of word lines WL, and the dummy word line DWL. The number of bit lines BL and word lines WL connected to the plurality of cell array stacks CS1, CS2, . . . , and CSn may be changed in various ways according to example embodiments, and thus, the number of first bonding pads B1 included in each of the plurality of cell array stacks CS1, CS2, . . . , and CSn may also be changed in various ways according to example embodiments.

The peripheral circuit stack PS may include at least some of the row decoder 32, the page buffer 34, and the control logic 38 included in the peripheral circuit 30 described with reference to FIG. 1. The row decoder 32 may include a word line driver 32A and a ground selection line/string selection line driver 32B. The peripheral circuit stack PS may further include a voltage generator and an input/output circuit. The peripheral circuit stack PS may include a plurality of second bonding pads B2 located at positions corresponding to the plurality of first bonding pads B1. A bonding structure of the first bonding pad B1 and the second bonding pad B2 may constitute a lower bonding structure BSL.

Some of the plurality of second bonding pads B2 may be connected between the plurality of bit lines BL and the page buffer 34, others of the plurality of second bonding pads B2 may be connected between the plurality of word lines WL and the dummy word line DWL, and the word line driver 32A, and others of the plurality of second bonding pads B2 may be connected between the ground selection line GSL and the string selection line SSL and the ground selection line/string selection line driver 32B.

A plurality of bonding structures including a plurality of third bonding pads B3 and a plurality of fourth bonding pads B4 may be located between the plurality of cell array stacks CS1, CS2, . . . , and CSn. The plurality of fourth bonding pads B4 may be located at positions corresponding to the plurality of third bonding pads B3. A bonding structure of the third bonding pad B3 and the fourth bonding pad B4 may constitute an upper bonding structure BSU.

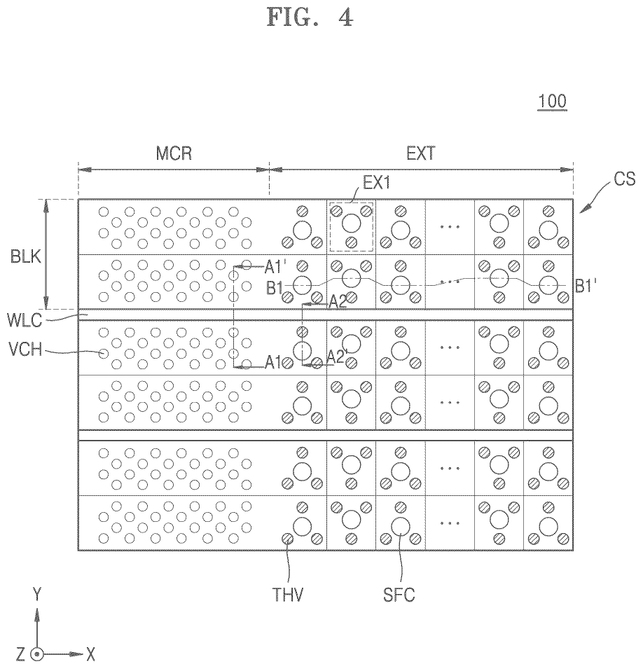

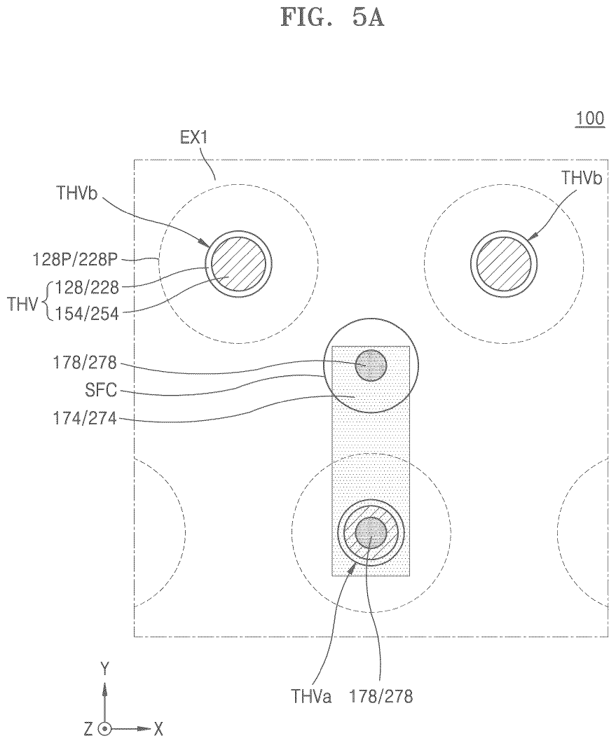

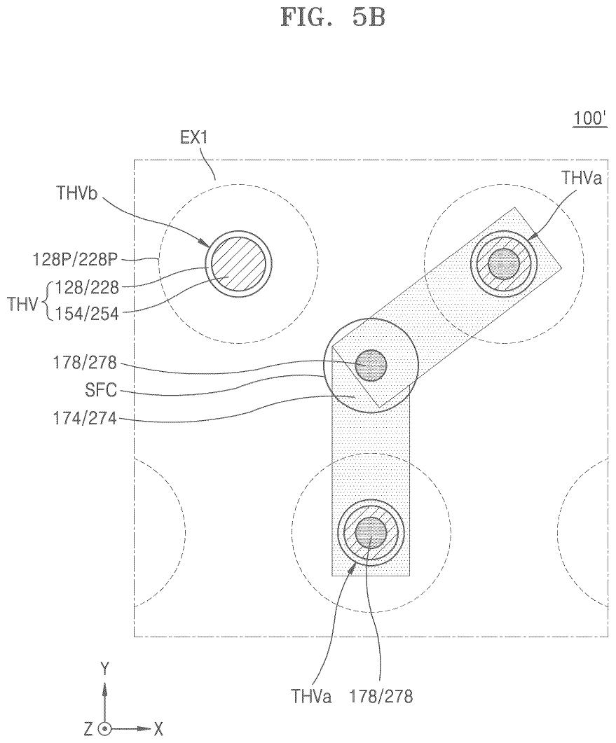

FIG. 4 is a plan layout view illustrating an area “A” in FIG. 3A. FIG. 5A is an enlarged view illustrating an example of an area “EX1” of FIG. 4. FIG. 5B is an enlarged view illustrating another example of the area “EX1” of FIG. 4.

Referring to FIGS. 4, 5A, and 5B, the memory device 100 may include the peripheral circuit stack PS and a plurality of cell array stacks CS located on the peripheral circuit stack PS to overlap the peripheral circuit stack PS in the vertical direction (Z direction). The plurality of cell array stacks CS may include the memory cell array 20 described with reference to FIG. 1, and the peripheral circuit stack PS may include the peripheral circuit 30 described with reference to FIG. 1.

The cell array stack CS may include a plurality of memory cell blocks BLK. The plurality of memory cell blocks BLK may correspond to the plurality of memory cell blocks BLK1, BLK2, . . . , and BLKn described with reference to FIG. 3A. Each of the plurality of memory cell blocks BLK may include memory cells that are three-dimensionally arranged. Each of the plurality of memory cell blocks BLK may have a planar shape extending long along the first horizontal direction (X direction) when viewed in a plan view (an X-Y plane in FIG. 4). Each of the plurality of memory cell blocks BLK may include the memory cell area MCR and the extension area EXT located on one side of the memory cell area MCR in the first horizontal direction (X direction).

Each of a plurality of word line cut structures WLC extending long in the first horizontal direction (X direction) in the memory cell area MCR and the extension area EXT may be located between the plurality of memory cell blocks BLK. The plurality of word line cut structures WLC may be spaced apart from each other in the second horizontal direction (Y direction). Each of the plurality of memory cell blocks BLK may be located between the plurality of word line cut structures WLC. The plurality of word line cut structures WLC may be located on both sides of each of the plurality of memory cell blocks BLK to define a width of each of the plurality of memory cell blocks BLK in the second horizontal direction (Y direction).

Each of the plurality of word line cut structures WLC may be formed of an insulating structure. In some example embodiments, the insulating structure may be formed of silicon oxide, silicon nitride, silicon oxynitride, or a low-k dielectric material. For example, the insulating structure may be formed of a silicon oxide film, a silicon nitride film, a SiON film, a SiOCN film, a SiCN film, or a combination thereof. In some other example embodiments, at least a part of the insulating structure may be formed as an air gap. The term “air” used herein may refer to the atmosphere or other gases that may be present during a manufacturing process.

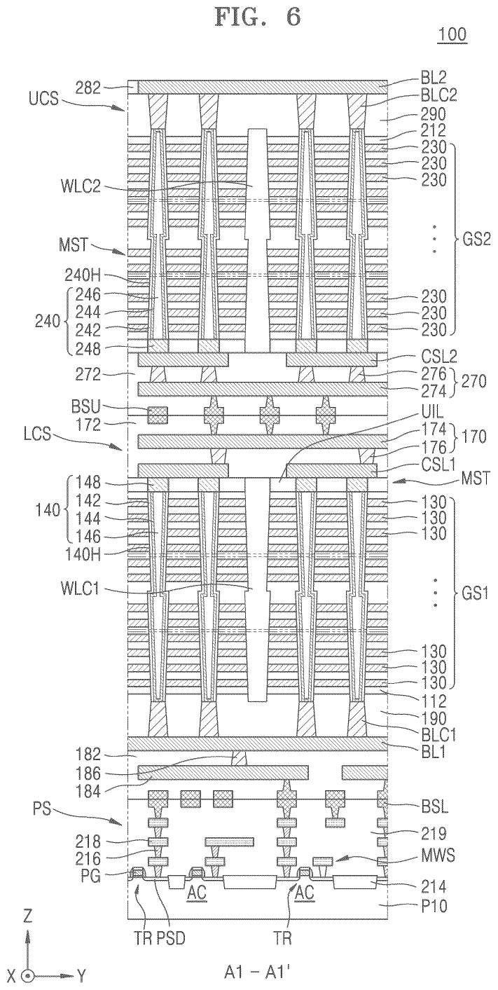

A string separation cut structure (not shown) may be further located to separate a first gate line 130 (see FIG. 6) (e.g., a lowermost gate line of FIG. 6) into two first gate lines 130 in one memory cell block BLK. A plurality of string separation cut structures (not shown) may be formed of an insulating film. In some example embodiments, the plurality of string separation cut structures (not shown) may include an insulating film formed of an oxide film, a nitride film, or a combination thereof.

The memory cell block BLK may include the cell array area MCR and the extension area EXT adjacent to the cell array area MCR in the first horizontal direction (X direction). In the memory cell block BLK, a plurality of vertical channel structures VCH may be located in the cell array area MCR. In the extension area EXT, a plurality of gate line contacts SFC, and a plurality of through-vias THV adjacent to the plurality of gate line contacts FC may be located.

The gate line contacts SFC may be spaced apart from each other in the first horizontal direction (X direction), and three through-vias THV arranged around each gate line contact SFC may surround the gate line contact SFC. However, the number of through-vias THV adjacent to each gate line contact SFC is not limited to 3, and may be 1, 2, or 4 or more.

The through-via THV may include conductive plugs 154/254 and insulating liners 128/228 surrounding the conductive plugs 154/254. The insulating liners 128/228 may include extending portions surrounding side walls of the conductive plugs 154/254 and protruding portions 128P/228P protruding from the extending portions in the first horizontal direction (X direction) and the second horizontal direction (Y direction).

In some example embodiments, as shown in FIGS. 5A and 5B, the protruding portions 128P/228P may be spaced apart from the gate line contact SFC without overlapping the gate line contact SFC in the vertical direction (Z direction).

The gate line contact SFC may be electrically connected to conductive studs 178/278 overlapping the gate line contact SFC in the vertical direction (Z direction). At least one through-via THV selected from among the plurality of through-vias THV adjacent to the gate line contact SFC may be electrically connected to the conductive studs 178/278 overlapping the through-via THV in the vertical direction (Z direction).

In an example embodiment, as shown in FIG. 5A, the conductive studs 178/278 overlapping the through-via THV in the vertical direction (Z direction) may be located on any one through-via THV selected from among the plurality of through-vias THV adjacent to the gate line contact SFC. In another example embodiment, as shown in FIG. 5B, the conductive studs 178/278 overlapping the through-vias THV in the vertical direction (Z direction) may be located on two or more through-vias THV selected from among the plurality of through-vias THV adjacent to the gate line contact SFC.

The gate line contact SFC may be electrically connected to wiring layers 174/274 through the conductive studs 178/278 on the gate line contact SFC, and at least one through-via THA selected from among the plurality of through-vias THV adjacent to the gate line contact SFC may be electrically connected to the wiring layers 174/274 through the conductive studs 178/278 on the through-via THV.

In an example embodiment, as shown in FIG. 5A, one through-via THV from among the plurality of through-vias THV adjacent to the gate line contact SFC may be electrically connected to the gate line contact SFC through the conductive studs 178/278 and the wiring layers 174/274. In another example embodiment, as shown in FIG. 5B, two or more through-vias THV from among the plurality of through-vias THV adjacent to the gate line contact SFC may be electrically connected to the gate line contact SFC through the conductive studs 178/278 and the wiring layers 174/274. The two or more through-vias THV may be electrically connected to the wiring layers 174/274 located at different vertical levels.

When the conductive studs 178/278 are located on two or more through-vias THV, respectively, even when a defect occurs in any one of the two or more through-vias THV, the gate line contact SFC may receive an electrical signal from a peripheral circuit through the other through-via THV, thereby relatively improving reliability of a memory element.

As shown in FIGS. 5A and 5B, the through-via THV configured to be electrically connected to the gate line contact SFC from among the plurality of through-vias THV may be referred to as a first vertical interconnect THVa, and the through-via THV configured not to be electrically connected to the gate line contact SFC from among the plurality of through-vias THV may be referred to as a second vertical interconnect THVb. Because the first vertical interconnect THVa and the second vertical interconnect THVb may be used together as a structure supporting the cell array stack CS, the structural stability and reliability of the memory element may be relatively improved.

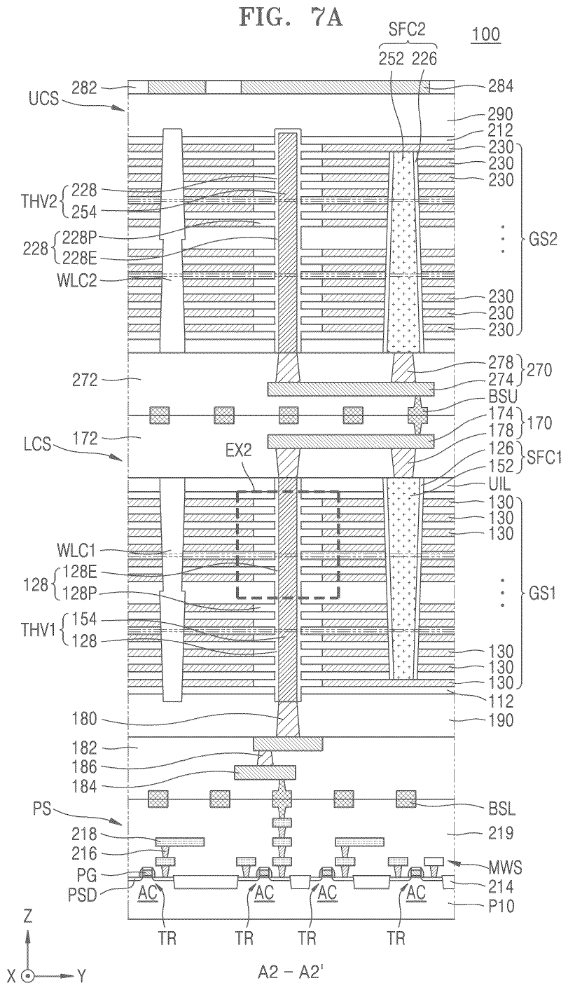

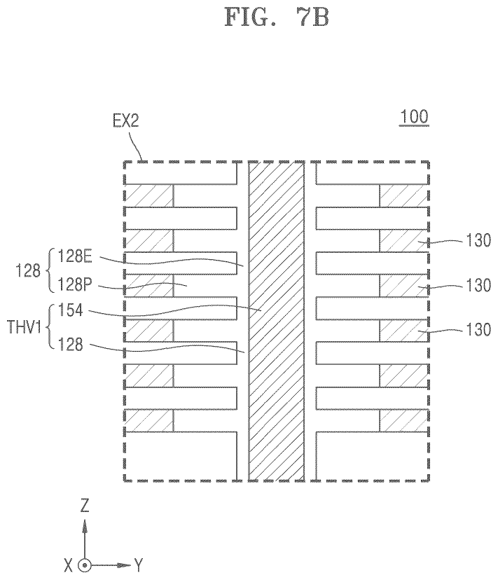

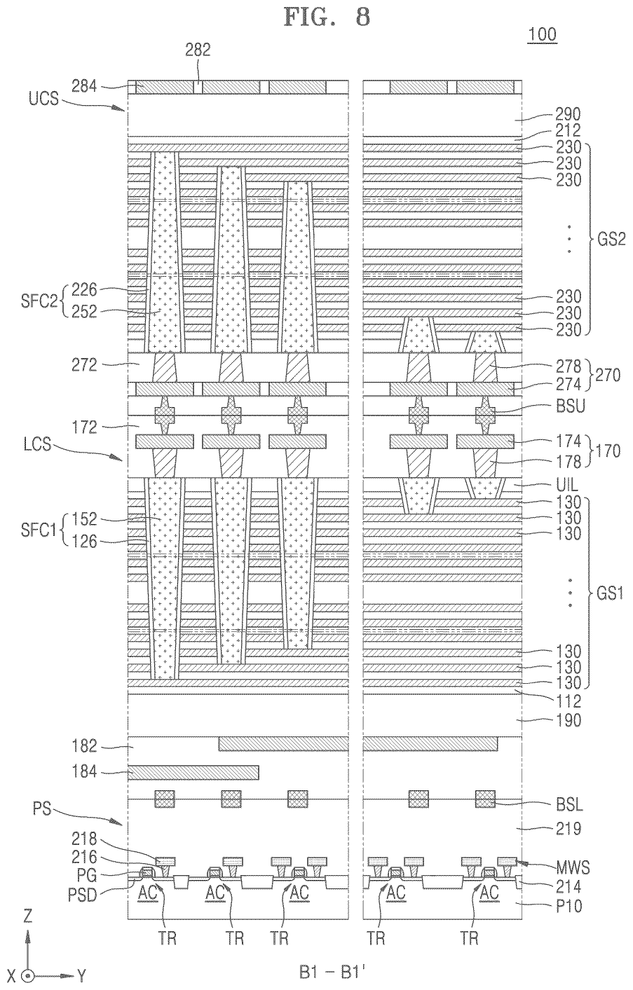

FIG. 6 is a cross-sectional view taken along line A1-A1′ of FIG. 4. FIG. 7A is a cross-sectional view taken along line A2-A2′ of FIG. 4. FIG. 7B is an enlarged view illustrating an area “EX2” of FIG. 7A. FIG. 8 is a cross-sectional view taken along line B1-B1′ of FIG. 4. A structure of the memory device 100 will be described in detail with reference to FIGS. 5, 6, 7A, 7B, and 8.

In the specification, from among the plurality of cell array stacks CS, the cell array stack CS closest to the peripheral circuit stack PS may be referred to as a lower cell array stack LCS, and the cell array stack CS over the lower cell array stack LCS may be referred to as an upper cell array stack UCS. The upper cell array stack UCS may be spaced apart from the peripheral stack PS with the lower cell array stack LCS therebetween in the vertical direction (Z direction).

In the specification, referring to FIG. 4 together, from among the plurality of vertical channel structures VCH, the plurality of vertical channel structures VCH included in the lower cell array stack LCS may be referred to as first vertical channel structures 140, and the plurality of vertical channel structures VCH included in the upper cell array stack UCS may be referred to as second vertical channel structures 240. From among the plurality of word line cut structures WLC, the plurality of word line cut structures WLC included in the lower cell array stack LCS may be referred to as first word line cut structures WLC1, and the plurality of word line cut structures WLC included in the upper cell array stack UCS may be referred to as second word line cut structures WLC2. From among the plurality of gate line contacts SFC, the plurality of gate line contacts SFC included in the lower cell array stack LCS may be referred to as first gate line contacts SFC1, and the plurality of gate line contacts SFC included in the upper cell array stack UCS may be referred to as second gate line contacts SFC2. From among the plurality of through-vias THV, the plurality of through-vias THV included in the lower cell array stack LCS may be referred to as first through-vias THV1, and the plurality of through-vias THV included in the upper cell array stack UCS may be referred to as second through-vias THV2.

The peripheral circuit stack PS may include a circuit board P10, a plurality of circuits located on the circuit board P10, and a multi-layer wiring structure MWS for connecting the plurality of circuits to each other or connecting the plurality of circuits to elements in the plurality of cell array stacks CS.

In the peripheral circuit stack PS, the circuit board P10 may include a semiconductor substrate. For example, the circuit board P10 may include Si, Ge, or SiGe. An active area AC may be defined in the circuit board P10 by a device isolation film 214. A plurality of transistors TR that constitute the plurality of circuits may be formed in the active area AC. Each of the plurality of transistors TR may include a gate PG and a plurality of ion implantation regions PSD formed in the active area AC on both sides of the gate PG. The plurality of ion implantation regions PSD may constitute a source region or a drain region of each transistor TR.

The plurality of circuits included in the peripheral circuit stack PS may include various circuits included in the peripheral circuit 30 described with reference to FIG. 1. In some example embodiments, the plurality of circuits included in the peripheral circuit stack PS may include the row decoder 32, the page buffer 34, the data input/output circuit 36, the control logic 38, and the common source line driver 39 of FIG. 1.

The multi-layer wiring structure MWS included in the peripheral circuit stack PS may include a plurality of peripheral circuit contacts 216 and a plurality of circuit wiring layers 218. At least some of the plurality of circuit wiring layers 218 may be configured to be electrically connected to the transistor TR. The plurality of peripheral circuit contacts 216 may be configured to connect some selected from among the plurality of circuit wiring layers 218 and the plurality of transistors TR.

Each of a plurality of conductive elements included in the lower cell array stack LCS and the upper cell array stack UCS may be configured to be connected to at least one selected from among the plurality of circuits through the multi-layer wiring structure MWS included in the peripheral circuit stack PS. Although the multi-layer wiring structure MWS includes three circuit wiring layers 218 along the vertical direction (Z direction) in FIGS. 6, 7A, and 8, example embodiments of the inventive concepts are not limited to that illustrated in FIGS. 6, 7A, and 8. For example, the multi-layer wiring structure MWS may include two circuit wiring layers 218, or four or more circuit wiring layers 218.

Each of the plurality of peripheral circuit contacts 216 and the plurality of circuit wiring layers 218 may be formed of metal, conductive metal nitride, metal silicide, or a combination thereof. For example, each of the plurality of peripheral circuit contacts 216 and the plurality of circuit wiring layers 218 may include a conductive material such as tungsten, molybdenum, titanium, cobalt, tantalum, nickel, tungsten silicide, titanium silicide, cobalt silicide, tantalum silicide, or nickel silicide.

The plurality of transistors TR and the multi-layer wiring structure MWS included in the peripheral circuit stack PS may be covered by a peripheral circuit insulating film 219. The peripheral circuit insulating film 219 may include silicon oxide, SiON, or SiOCN.

The lower cell array stack LCS may include a first insulating film 190 on the peripheral circuit stack PS, a plurality of first gate insulating films 112 and a plurality of first gate lines 130 alternately stacked on the first insulating film 190 in the memory cell area MCR (see FIG. 4), and a first common source line CSL1. The plurality of first gate lines 130 may constitute a first gate stack GS1.

The first common source line CSL1 may perform a function of the common source line CSL described with reference to FIG. 1 and may correspond to the first common source line CSL1 described with reference to FIG. 2. For example, the first common source line CSL1 may function as a source region that supplies current to vertical memory cells included in the lower cell array stack LCS. The first common source line CSL1 may be spaced apart from an upper surface of the first insulating film 190 in the vertical direction (Z direction) with the first gate stack GS on the first insulating film 190 therebetween.

In some example embodiments, the first insulating film 190 may be formed of an insulating film such as an oxide film or a silicon oxide film. The first common source line CSL1 may be formed of a doped polysilicon film, a metal film, or a combination thereof. The metal film may be formed of, but not limited to, tungsten (W). Each of the plurality of first gate lines 130 may be formed of metal, metal silicide, a semiconductor doped with impurities, or a combination thereof. For example, each of the first gate lines 130 may include metal such as tungsten, nickel, cobalt, or tantalum, metal silicide such as tungsten silicide, nickel silicide, cobalt silicide, or tantalum silicide, doped polysilicon, or a combination thereof.

The plurality of first gate lines 130 may extend parallel to each other in the horizontal direction (X direction and Y direction in FIG. 6) and may overlap each other in the vertical direction (Z direction). The first gate insulating film 112 may be located between the plurality of first gate lines 130. In this case, the first gate insulating film 112 may be located over the first gate line 130 that is an uppermost first gate line from among the plurality of first gate lines 130, and the first gate insulating film 112 may be located under the first gate line 130 that is a lowermost first gate line from among the plurality of first gate lines 130. The first gate insulating film 112 may be formed of silicon oxide.

In the memory cell area MCR (see FIG. 4), a plurality of first vertical channel structures 140 may be located on the first insulating film 190. The plurality of first vertical channel structures 140 may extend long in the vertical direction (Z direction) by passing through the plurality of first gate lines 130, the plurality of first gate insulating films 112, and a portion of the first insulating film 190 that are on the peripheral circuit stack PS. The plurality of first vertical channel structures 140 may be arranged at certain intervals to be spaced apart from each other along the first horizontal direction (X direction) and the second horizontal direction (Y direction).

Each of the plurality of first vertical channel structures 140 may include a gate dielectric film 142, a channel region 144, a buried insulating film 146, and a capping film 148. Each of the plurality of first vertical channel structures 140 may be a structure formed in a channel hole 140H passing through a first gate stack GS1 and the first gate insulating film 112. In an example embodiment, the gate dielectric film 142 may conformally cover a side wall of the channel hole 140H, the channel region 144 may conformally cover a side wall of the gate dielectric film 142 and the bottom of the channel hole 140H, and the buried insulating film 146 may fill a remaining space of the channel hole 140H on the channel region 144. In this case, the channel region 144 may be formed in a cylindrical shape. The capping film 148 contacting the channel region 144 may be located on the gate dielectric film 142, the channel region 144, and the buried insulating film 146. In another example embodiment, the buried insulating film 146 may be omitted, and the channel region 144 may be formed in a pillar shape filling a remaining space of the channel hole 140H on the gate dielectric film 142.

In some example embodiments, the gate dielectric film 142 may include a tunneling dielectric film, a charge storage film, and a blocking dielectric film which are sequentially formed. The tunneling dielectric film may include silicon oxide, hafnium oxide, aluminum oxide, zirconium oxide, or tantalum oxide. The charge storage film is an area where electrons passing through the tunneling dielectric film from the channel region 144 may be stored, and the charge storage film may include silicon nitride, boron nitride, silicon boron nitride, or polysilicon doped with impurities. The blocking dielectric film may be formed of silicon oxide, silicon nitride, or a metal oxide with a higher dielectric constant than silicon oxide. The metal oxide may be formed of or include hafnium oxide, aluminum oxide, zirconium oxide, tantalum oxide, or a combination thereof. In some example embodiments, the channel region 144 may include doped polysilicon or undoped polysilicon. In some example embodiments, the buried insulating film 146 may be formed of or include silicon oxide, silicon nitride, silicon oxynitride, or a combination thereof. In some example embodiments, the capping film 148 may be formed of or include a doped polysilicon film. The capping films 148 may be insulated from each other by an upper insulating film UIL.

The plurality of first vertical channel structures 140 are not limited to the structures shown in FIG. 6. For example, a configuration in which the plurality of first vertical channel structures 140 are connected to the first common source line CSL1 may be modified in various ways.

One end of the plurality of first vertical channel structures 140 may contact a first bit line contact BLC1 passing through at least a part of the first insulating film 190, and the other end of the plurality of first vertical channel structures 140 may contact the first common source line CSL1.

In some example embodiments, the first bit line contact BLC1 and a first bit line BL1 may be located between the plurality of first vertical channel structures 140 and the peripheral circuit stack PS. The plurality of first vertical channel structures 140 may be electrically connected to the first bit line BL1 through the first bit line contact BLC1. A first lower wiring layer 184 and a first lower contact plug 186 may be located under the first bit line BL1. The first bit line BL1 may be electrically connected to the first lower wiring layer 184 by the first lower contact plug 186 located between the first bit line BL1 and the first lower wiring layer 184. Surfaces of the first bit line BL1, the first lower wiring layer 184, and the first lower contact plug 186 may be covered by a first lower insulating film 182.

In some example embodiments, a plurality of first common source lines CSL1 may be spaced apart from the circuit stack PS with the plurality of first vertical channel structures 140 therebetween. A first upper wiring layer 174 and a first upper contact plug 176 may be located on the plurality of first common source lines CSL1. The plurality of first common source lines CSL1 may be electrically connected to the first upper wiring layer 174 by the first upper contact plug 176 located between the plurality of first common source lines CSL1 and the first upper wiring layer 174. Surfaces of the plurality of first common source lines CSL1, the first upper wiring layer 174, and the first upper contact plug 176 may be covered by a first upper insulating film 172.

The first word line cut structure WLC1 may be located adjacent to the plurality of first vertical channel structures 140, in the second horizontal direction (Y direction) of the plurality of first vertical channel structures 140. The first word line cut structure WLC1 may extend long in the vertical direction (Z direction) by passing through the plurality of first gate lines 130 and the plurality of first gate insulating films 112 on the first insulating film 190. The first word line cut structures WLC1 may be arranged at certain intervals to be spaced apart from each other along the second horizontal direction (Y direction).

As shown in FIGS. 7A and 7B, in the extension area EXT, the first through-via THV1 may be located on the first insulating film 190. The first through-via THV1 may be spaced apart from the first word line cut structure WLC1 in the second horizontal direction (Y direction). The first through-via (THV1) may extend long in the vertical direction (Z direction) by passing through the plurality of first gate lines 130 and the plurality of first gate insulating films 112 on the first insulating film 190. In some example embodiments, the first through-via THV1 may include a first conductive plug 154 and a first insulating liner 128 surrounding a side wall of the first conductive plug 154.

The first insulating liner 128 may include a first extending portion 128E extending along the side wall of the first conductive plug 154 and a plurality of first protruding portions 128P protruding from the extending portion in the first horizontal direction (X direction) and the second horizontal direction (Y direction). The plurality of first protruding portions 128P may overlap the plurality of first gate lines 130 in the second horizontal direction (Y direction). Also, the plurality of first protruding portions 128P may be arranged along the side wall of the first extending portion 128E, and may be spaced apart from each other in the vertical direction (Z direction) with the first gate insulating film 112 therebetween. In some example embodiments, the first conductive plug 154 may be formed of or include, but not limited to, tungsten, titanium, tantalum, copper, aluminum, titanium nitride, tantalum nitride, tungsten nitride, or a combination thereof. In some example embodiments, the first insulating liner 128 may be formed of oxide or silicon oxide.

One end of the first through-via THV1 may contact a first through contact 180 passing through at least a part of the first insulating film 190, and the other end of the first through-via THV1 may contact a first conductive stud 178.

In some example embodiments, the first through contact 180 may be located between the first through-via THV1 and the peripheral circuit stack PS. In other example embodiments, the first through contact 180 may be omitted, and the first through-via THV1 may extend until one end of the first through-via THV1 contacts the first lower wiring layer 184.

The first through-via THV1 may be electrically connected to the first lower wiring layer 184 and may be electrically connected to any one selected from among a plurality of peripheral circuits located in the peripheral circuit stack PS. For example, the peripheral circuit electrically connected to the first through-via THV1 may include the row decoder 32 (see FIG. 1) (e.g., XDEC), and the first through-via THV1 may be configured to receive a word line driving voltage or a pass voltage from the peripheral circuit.

In some example embodiments, a first wiring structure 170 may be spaced apart from the peripheral circuit stack PS with the first through-via THV1 therebetween. The first wiring structure 170 may include a plurality of first conductive studs 178 and a first upper wiring layer 174 on the plurality of first conductive studs 178, and a surface of the first wiring structure 170 may be covered by the first upper insulating film 172. The plurality of first conductive studs 178 may be located on an upper surface of the first through-via THV1 and an upper surface of the first gate line contact SFC1, respectively.

As shown in FIG. 8, in the extension area EXT, a plurality of first gate line contacts SFC1 may be located on the first insulating film 190. The plurality of first gate line contacts SFC1 may extend in the vertical direction (Z direction) by passing through the plurality of first gate lines 130 and the plurality of first gate insulating films 112 on the first insulating film 190. The plurality of first gate line contacts SFC1 may be arranged to be spaced apart from each other in the first horizontal direction (X direction). In this case, the plurality of first gate line contacts SFC1 may have different vertical lengths and may be physically and electrically connected to different first gate lines 130. In some example embodiments, vertical lengths of the plurality of first gate line contacts SFC1 may decrease as a distance from the cell array area MCR (see FIG. 4) increases along the first horizontal direction (X direction), and vertical levels of bottom surfaces of the plurality of first gate line contacts SFC1 may increase as a distance from the cell array area MCR (see FIG. 4) increases along the first horizontal direction (X direction). However, the plurality of first gate line contacts SFC1 are not limited to having vertical lengths that decrease as a distance from the cell array area MCR (see FIG. 4) increases along the first horizontal direction (X direction), and the plurality of first gate line contacts SFC1 may be arranged in various shapes.

The plurality of first gate line contacts SFC1 may include a first gate contact plug 152 and a first gate insulating spacer 126 surrounding a side wall of the first gate contact plug 152. In some example embodiments, the first gate contact plug 152 may be formed of or include, but not limited to, tungsten, titanium, tantalum, copper, aluminum, titanium nitride, tantalum nitride, tungsten nitride, or a combination thereof. In some example embodiments, the first gate insulating spacer 126 may be formed of or include oxide or silicon oxide.

As shown in FIGS. 7A and 8, the first through-via THV1 and the first gate line contact SFC1 may be electrically connected to the first wiring structure 170. The first through-via THV1 may be electrically connected to the first gate line contact SFC1 adjacent to the first through-via THV1 from among the plurality of first gate line contacts SFC1 through the first wiring structure 170.

The first through-via THV1 may be electrically connected to the adjacent first gate line contact SFC1 and may be electrically connected to the first gate line 130 electrically connected to the first gate line contact SFC1 from among the plurality of first gate lines 130 of the lower cell array stack LCS.

The first through-via THV1 may receive a word line driving voltage or a pass voltage from any one of the plurality of peripheral circuits of the peripheral circuit stack PS electrically connected to the first through-via THV1 and may apply a word line driving voltage or a pass voltage to the first gate line 130 electrically connected to the first through-via THV1. For example, the first through-via THV1 may receive a pass voltage from the row decoder 32 (see FIG. 1) (e.g., XDEC) electrically connected to the first through-via THV1 to enable the first gate line 130 electrically connected to the first through-via THV1.

The upper cell array stack UCS may have a structure similar to that described for the lower cell array stack LCS. The upper cell array stack UCS may overlap the peripheral circuit stack PS in the vertical direction (Z direction) with the lower cell array stack LCS therebetween.

The upper cell array stack UCS may include a second insulating film 290 on the lower cell array stack LCS, a plurality of second gate insulating films 212 and a plurality of second gate lines 230 alternately stacked on the second insulating film 290, and a second common source line CSL2. The plurality of second gate lines 230 may constitute the second gate stack GS2.

The second common source line CSL2 may perform a function of the common source line CSL described with reference to FIG. 1 and may correspond to the second common source line CSL2 described with reference to FIG. 2. For example, the second common source line CSL2 may function as a source region that supplies current to vertical memory cells included in the upper cell array stack UCS. The second common source line CSL2 may be spaced apart from a bottom surface of the second insulating film 290 in the vertical direction (−Z direction) with the second gate stack GS2 on the second insulating film 290 therebetween.

In some example embodiments, the second insulating film 290 and the second common source line CSL2 may be formed of materials similar to those described for the first insulating film 190 and the first common source line CSL1.

In the memory cell area MCR (see FIG. 4), a plurality of second vertical channel structures 240 may be located on the second insulating film 290. The plurality of second vertical channel structures 240 may extend long in the vertical direction (Z direction) by passing through the plurality of second gate lines 230 and the plurality of second gate insulating films 212 between the lower cell array stack LCS and the second insulating film 290. The plurality of second vertical channel structures 240 may be arranged at certain intervals to be spaced apart from each other along the first horizontal direction (X direction) and the second horizontal direction (Y direction). The plurality of second vertical channel structures 240 may be configured in a similar manner to the plurality of first vertical channel structures 140. For example, like the plurality of first vertical channel structures 140, each of the plurality of second vertical channel structures 240 may include a gate dielectric film, a channel region, a buried insulating film, and a capping film. However, each of the plurality of first vertical channel structures 140 has a shape whose horizontal width decreases downward, but each of the plurality of second vertical channel structures 240 may have a shape whose horizontal width decreases upward. Also, the capping film 248 of the plurality of second vertical channel structures 240 may be located at a lowest vertical level in the plurality of second vertical channel structures 240, and the capping film 148 of the plurality of first vertical channel structures 140 may be located at a highest vertical level in the plurality of first vertical channel structures 140.

The plurality of second vertical channel structures 240 are not limited to a structure shown in FIG. 6. For example, a configuration in which the plurality of second vertical channel structures 240 are connected to the second common source line CSL2 may be modified in various ways.

One end of the plurality of second vertical channel structures 240 may contact a second bit line contact BLC2 passing through at least a part of the second insulating film 290, and the other end of the plurality of second vertical channel structures 240 may contact the second common source line CSL2.

In some example embodiments, the second bit line contact BLC2 and a second bit line BL2 may be spaced apart from the lower cell array stack LCS with the plurality of second vertical channel structures 240 therebetween. The plurality of second vertical channel structures 240 may be electrically connected to the second bit line BL2 through the second bit line contact BLC2. A surface of the second bit line BL2 may be covered by a second upper insulating film 282.

In some example embodiments, a plurality of second common source lines CSL2 may be located between the plurality of second vertical channel structures 240 and the lower cell array stack LCS. A second lower wiring layer 274 and a second lower contact plug 276 may be located under the plurality of second common source lines CSL2. The plurality of second common source lines CSL2 may be electrically connected to the second lower wiring layer 274 by the second lower contact plug 276 located between the plurality of second common source lines CSL2 and the second lower wiring layer 274. Surfaces of the plurality of second common source lines CSL2, the second lower wiring layer 274, and the second lower contact plug 276 may be covered by a second lower insulating film 272.

The second word line cut structure WLC2 may be located adjacent to the plurality of second vertical channel structures 240 in the second horizontal direction (Y direction) of the plurality of second vertical channel structures 240. The second word line cut structure WLC2 may extend long in the vertical direction (Z direction) by passing through the plurality of second gate lines 230 and the plurality of second gate insulating films 212 between the lower cell array stack LCS and the second insulating film 290.

As shown in FIGS. 7A and 7B, in the extension area EXT, the second through-via THV2 may be located on the second insulating film 290. The second through-via THV2 may be spaced apart from the second word line cut structure WLC2 in the second horizontal direction (Y direction). The second through-via THV2 may extend long in the vertical direction (Z direction) by passing through the plurality of second gate lines 230 and the plurality of second gate insulating films 212 on the second insulating film 290. Like the first through-via THV1, the second through-via THV2 may include a second conductive plug 254 and a second insulating liner 228 surrounding a side wall and an upper surface of the second conductive plug 254. A part of the second insulating liner 228 may be located between the second insulating film 290 and the second conductive plug 254. The second insulating liner 228 may include a second extending portion 228E extending along the side wall of the second conductive plug 254 and a plurality of second protruding portions 228P protruding from the second extending portion 228E in the horizontal direction (X direction or Y direction).

One end of the second through-via THV2 may be surrounded by the second insulating film 290, and the other end of the second through-via THV2 may contact a second conductive stud 278. The one end of the second through-via THV2 may be spaced apart from a second upper wiring layer 284 with a part of the second insulating film 290 therebetween.

In some example embodiments, a second wiring structure 270 may be located between the second through-via THV2 and the lower cell array stack LCS. The second wiring structure 270 may include a plurality of second conductive studs 278 and a second lower wiring layer 274 on the plurality of second conductive studs 278, and a surface of the second wiring structure 270 may be covered by the second lower insulating film 272. The plurality of second conductive studs 278 may be located on a bottom surface of the second through-via THV2 and a bottom surface of the second gate line contact SFC2.

As shown in FIG. 8, in the extension area EXT, a plurality of second gate line contacts SFC2 may be located on the second insulating film 290. The plurality of second gate line contacts SFC2 may extend in the vertical direction (Z direction) by passing through the plurality of second gate lines 230 and the plurality of second gate insulating films 212 on a second insulating film 290. In this case, the plurality of second gate line contacts SFC2 may have different vertical lengths and may be physically and electrically connected to different second gate lines 230. In some example embodiments, the plurality of second gate line contacts SFC2 may be arranged to be spaced apart from each other in the first horizontal direction (X direction). Vertical lengths of the plurality of second gate line contacts SFC2 may decrease as a distance from the cell array area MCR (see FIG. 4) increases along the first horizontal direction (X direction), and vertical levels of upper surfaces of the plurality of second gate line contacts SFC2 may decrease as a distance from the cell array area MCR (see FIG. 4) increases along the first horizontal direction (X direction). However, the plurality of second gate line contacts SFC2 are not limited to having vertical lengths that decrease as a distance from the cell array area MCR (see FIG. 4) increases along the first horizontal direction (X direction), and the plurality of second gate line contacts SFC2 may be arranged in various shapes.

In some example embodiments, any one selected from among the plurality of first gate line contacts SFC1 and the second gate line contact SFC2 electrically connected to the selected first gate line contact SFC1 may have the same vertical length. In other words, when any one selected from among the plurality of first gate line contacts SFC1 contacts any one selected from among the plurality of first gate lines 130, the second gate line contact SFC2 electrically connected thereto may contact the corresponding second gate line 230. For example, when any one selected from among the plurality of first gate line contacts SFC1 contacts the first gate line 130 that is a lowermost first gate line, the second gate line contact SFC2 electrically connected thereto may contact the second gate line 230 that is an uppermost second gate line.

Like the plurality of first gate line contacts SFC1, each of the plurality of second gate line contacts SFC2 may include a second gate contact plug 252 and a second gate insulating spacer 226 surrounding a side wall of the second gate contact plug 252. However, while each of the plurality of first gate line contacts SFC1 has a shape whose horizontal width decrease downward, each of the plurality of second gate line contacts SFC2 may have a shape whose horizontal width decreases upward.

As shown in FIGS. 7A and 8, the second through-via THV2 and the second gate line contact SFC2 may be electrically connected to the second wiring structure 270. For example, the second through-via THV2 may be electrically connected to the second gate line contact SFC2 adjacent to the second through-via THV2 from among the plurality of second gate line contacts SFC2 through the second wiring structure 270.

The first through-via THV1 may be electrically connected to the adjacent first gate line contact SFC1 to be electrically connected to the first gate line 130, which is electrically connected to the first gate line contact SFC1, from among the plurality of first gate lines 130 of the lower cell array stack LCS as described above. Also, the first through-via THV1 may be electrically connected to the adjacent second gate line contact SFC2 through the first wiring structure 170, an upper bonding structure BSU, and the second wiring structure 270 to be electrically connected to the second gate line 230 electrically connected to the second gate line contact SFC2 from among the plurality of second gate lines 230 of the upper cell array stack UCS.

The first through-via THV1 may receive a word line driving voltage or a pass voltage from any one of the plurality of peripheral circuits of the peripheral circuit stack PS electrically connected to the first through-via THV1 and may apply a word line driving voltage or a pass voltage to the first gate line 130 of the lower cell array stack LCS, which is electrically connected to the first through-via THV1, and the second gate line 230 of the upper cell array stack UCS electrically connected to the first through-via THV1. For example, the first through-via THV1 may receive a pass voltage from the row decoder 32 (see FIG. 1) (e.g., XDEC) electrically connected to the first through-via THV1 to enable the first gate line 130 of the lower cell array stack LCS electrically connected to the first through-via THV1 and the second gate line 230 of the upper cell array stack UCS.

A plurality of lower bonding structures BSL may be located between the peripheral circuit stack PS and the first lower wiring layer 184 included in the lower cell array stack LCS, and a plurality of upper bonding structures BSU may be located between the lower cell array stack LCS and the upper cell array stack UCS. Each of the plurality of lower bonding structures BSL may include, as a pair, a first bonding metal pad included in the lower cell array stack LCS and a second bonding metal pad included in the peripheral circuit stack PS. Each of the plurality of upper bonding structures BSU may include, as a pair, a first bonding metal pad included in the upper cell array stack UCS and a second bonding metal pad included in the lower cell array stack LCS. Each of the first bonding metal pad and the second bonding metal pad may be formed of or include, but not limited to, copper, aluminum, or tungsten. The first bonding metal pad and the second bonding metal pad may be integrated and coupled to each other.

The second bit line BL2 included in the upper cell array stack UCS may be configured to be connected to the page buffer 34 (see FIGS. 1 and 3B) through conductive structures included in the upper cell array stack UCS under the second bit line BL2, the upper bonding structure BSU, conductive structures included in the lower cell array stack LCS, and the lower bonding structure BSL.

According to some example embodiments, a plurality of through-vias (e.g., THV1 and THV2) may be arranged around a plurality of gate line contacts (e.g., SFC1 and SFC2) to structurally support the lower cell array stack LCS and the upper cell array stack UCS, and at least one of the plurality of through-vias (e.g., THV1 and THV2) may be electrically connected to corresponding gate line contacts SFC1 and SFC2 from among the plurality of gate line contacts (e.g., SFC1 and SFC2) to transmit a word line driving voltage or a pass voltage to the gate line contacts (e.g., SFC1 and SFC2), thereby relatively improving integration and reliability.

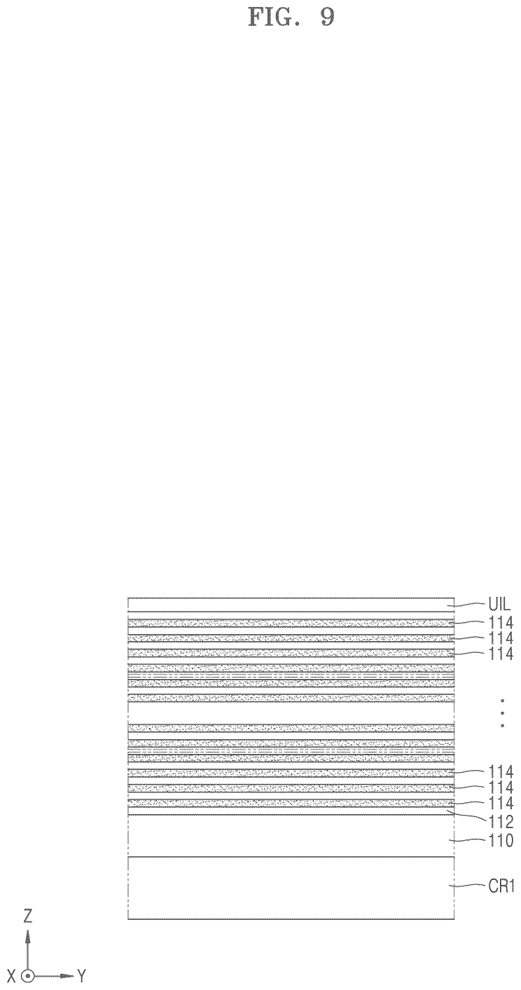

FIGS. 9 to 24 are cross-sectional views sequentially illustrating a process order of a manufacturing method, according to an example embodiment. A method of manufacturing the memory device 100 described with reference to FIGS. 4, 5A, 5B, 6, 7A, 7B, and 8 will be described with reference to FIGS. 9 to 24. In FIGS. 9 to 24, the same members as those in FIGS. 4, 5A, 5B, 6, 7A, 7B, and 8 are denoted by the same reference numerals, and thus, a detailed description thereof will be omitted. FIGS. 9 to 24 may be cross-sectional views taken along line A2-A2′ of FIG. 4.

Referring to FIG. 9, in the extension area EXT, a first substrate 110 may be formed on a first carrier substrate CR1, and a stacked structure in which the plurality of first gate insulating films 112 and the plurality of sacrificial insulating films 114 are alternately stacked may be formed on the first substrate 110. The plurality of first gate insulating films 112 may each be formed of or include a silicon oxide film, and the plurality of sacrificial insulating films 114 may each be formed of or include a silicon nitride film. The plurality of sacrificial insulating films 114 may secure a space for forming the plurality of gate lines 130 (see FIG. 7A) in a subsequent process. In the stacked structure, the first gate insulating films 112 may be located at lowermost and uppermost positions. Next, the upper insulating film UIL covering an upper surface of the stacked structure may be formed.

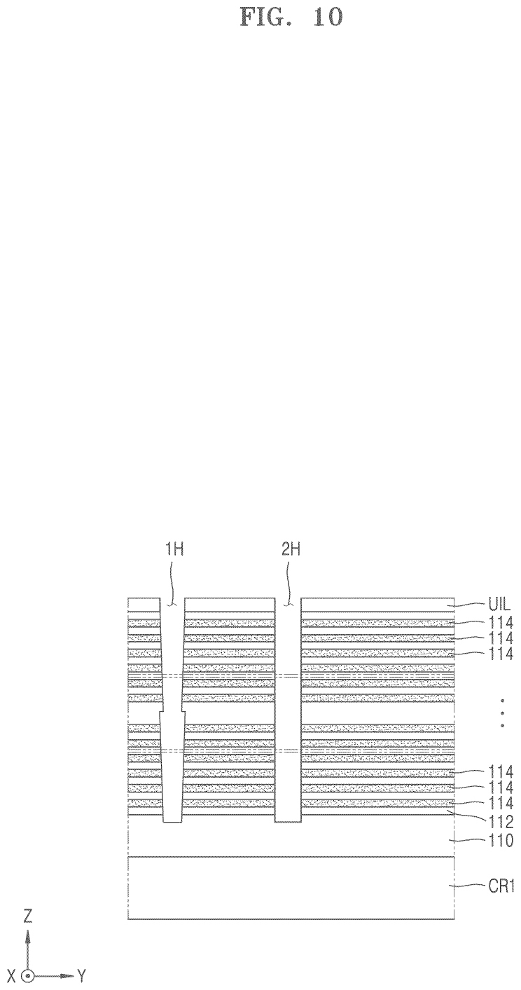

Referring to FIG. 10, a first hole 1H and a second hole 2H passing through the upper insulating film UIL and the stacked structure of FIG. 9 may be formed. The first hole 1H may be for forming the first word line cut structure WLC1 (see FIG. 7A), and the second hole 2H may be for forming the first through-via THV1 (see FIG. 7A). To form the first hole 1H and the second hole 2H, an etching process may be performed on the upper insulating film UIL and a part of the stacked structure, and the etching process may include a dry etching process, a wet etching process, or a combination thereof.

In some example embodiments, the second hole 2H may partially pass through the first substrate 110, and a vertical level of the bottom of the second hole 2H may be located between a vertical level of an upper surface and a vertical level of a bottom surface of the first substrate 110. In other example embodiments, the second hole 2H may entirely pass through the first substrate 110, and a vertical level of the bottom of the second hole 2H may be the same as a vertical level of the bottom surface of the first substrate 110.

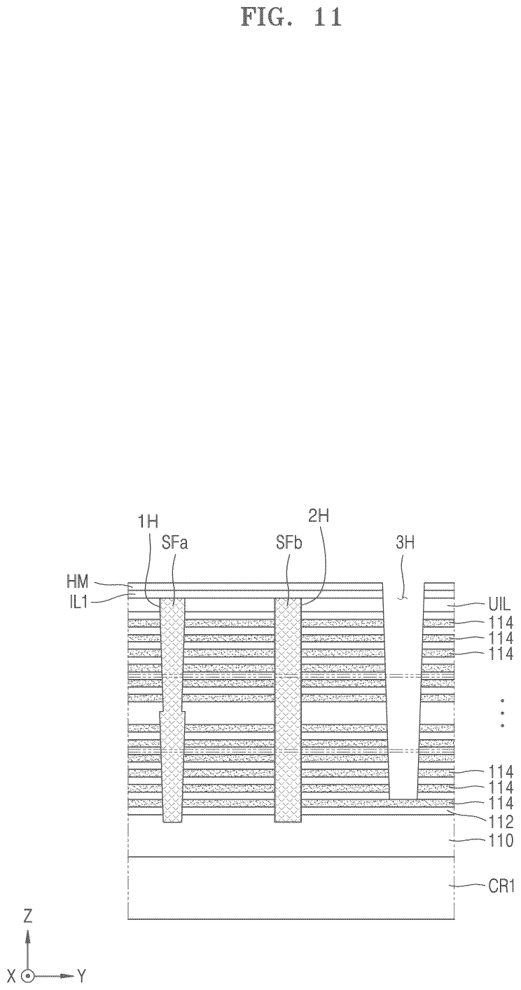

Referring to FIG. 11, a first sacrificial film SFa filling the inside of the first hole 1H of FIG. 10 and a second sacrificial film SFb filling the inside of the second hole 2H may be formed. Each of the first sacrificial film SFa and the second sacrificial film SFB may be formed of or include, but not limited to, a conductive material such as tungsten, a silicon film, a polycrystalline silicon film, or a carbide film.

A first cover insulating film IL1 may be formed on a resultant structure where the first sacrificial film SFa and the second sacrificial film SFb are formed. The first cover insulating film IL1 may be formed of or include, but not limited to, a silicon oxide film. Next, a hard mask HM including a plurality of holes corresponding to positions of the plurality of gate line contacts SFC (see FIG. 7A) may be formed on the first cover insulating film IL1, and a third hole 3H passing through the first cover insulating film IL1, the upper insulating film UIL, and the stacked structure may be formed through the plurality of holes. The third hole 3H may be for forming the gate line contact SFC (see FIG. 7A). To form the third hole 3H, an etching process may be performed on the first cover insulating film IL1, the upper insulating film UIL, and a part of the stacked structure, and the etching process may include a dry etching process, a wet etching process, or a combination thereof.

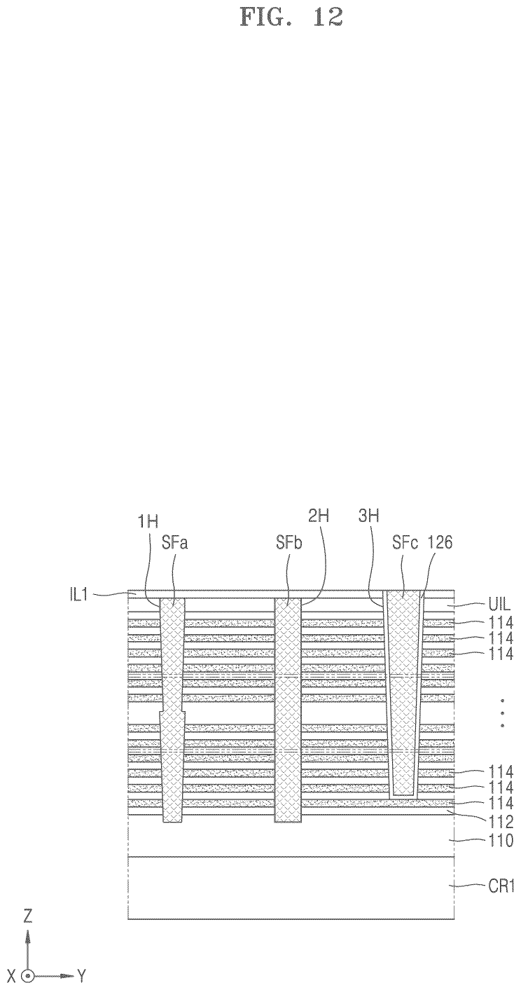

Referring to FIG. 12, the hard mask HM (see FIG. 11) may be removed from a resultant structure of FIG. 11, and the first gate insulating spacer 126 may be formed in the third hole 3H. The first gate insulating spacer 126 may be formed to conformally cover an inner wall and a bottom of the third hole 3H. A third sacrificial film SFc may be formed in the third hole 3H on which the first gate insulating spacer 126 is formed. The third sacrificial film SFc may fill a remaining space of the third hole 3H on which the first gate insulating spacer 126 is formed. Like the first sacrificial film SFa and the second sacrificial film SFb, the third sacrificial film SFc may be formed of or include, but not limited to, a conductive material such as tungsten, a silicon film, a polycrystalline silicon film, or a carbide film.

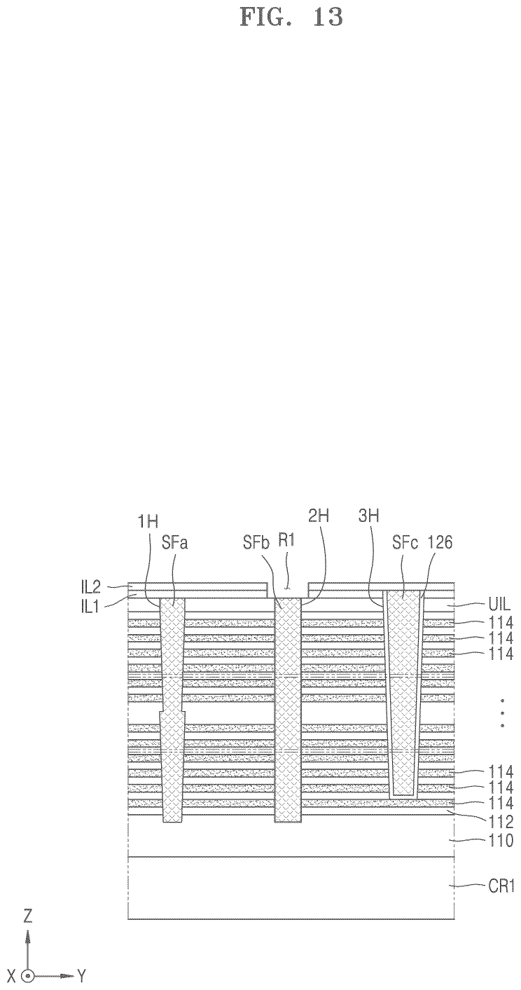

Referring to FIG. 13, a second cover insulating film IL2 covering a resultant structure of FIG. 12 may be formed, and a first recess R1 passing through the second cover insulating film IL2 and the first cover insulating film IL1 may be formed. The second sacrificial film SFb in the second hole 2H may be exposed from the bottom of the first recess R1. In this case, an upper surface of the first sacrificial film SFa may be covered by the first cover insulating film IL1 and the second cover insulating film IL2 without being exposed, and an upper surface of the third sacrificial film SFc may be covered by the second cover insulating film IL2 without being exposed.

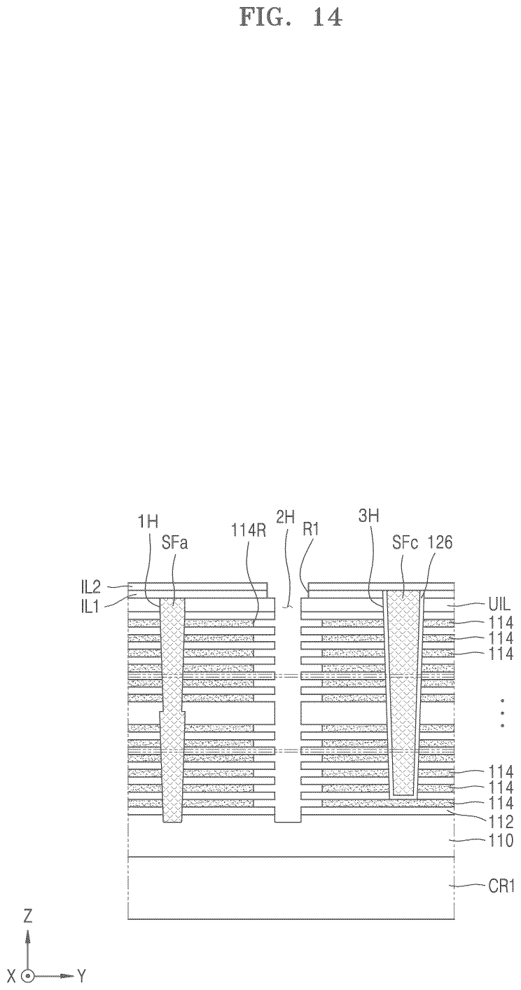

Referring to FIG. 14, the second sacrificial film SFb in the second hole 2H may be removed through the first recess R1 of FIG. 13. The second sacrificial film SFb may be removed and the plurality of sacrificial insulating films 114 may be exposed through a side wall of the second hole 2H. Through the second hole 2H, a sacrificial insulating film recess 114R may be formed by etching parts of the plurality of sacrificial insulating films 114 exposed through the side wall of the second hole 2H. The etching process may be a selective etching process using that the plurality of sacrificial insulating films 114 have a different etch selectivity from the plurality of first gate insulating films 112. Also, the etching process may be a wet etching process. Through the etching process, the second hole 2H may protrude so that a side wall facing the plurality of sacrificial insulating films 114 protrudes farther from the center in the Y direction, of the second hole 2H than a side wall facing the plurality of first gate insulating films 112.

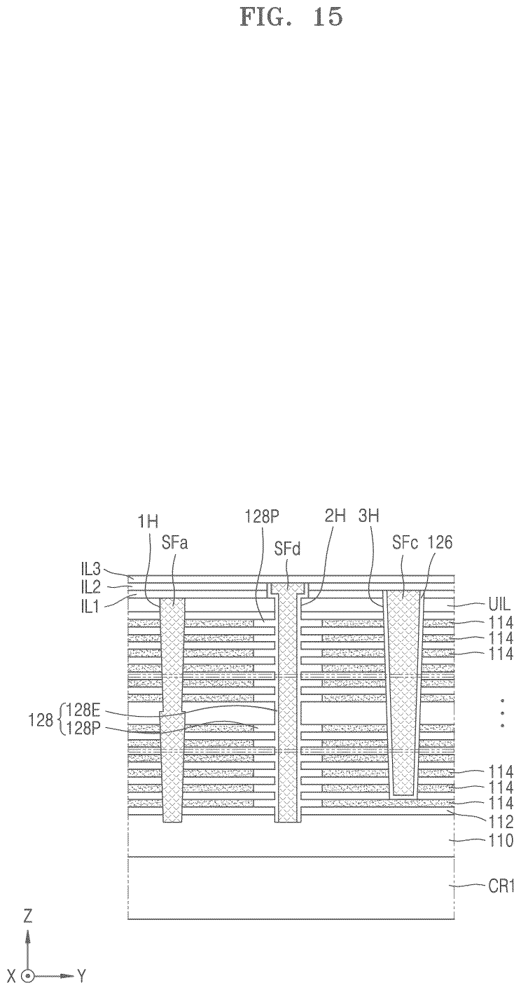

Referring to FIG. 15, In some example embodiments, the first insulating liner 128 filling the sacrificial insulating film recess 114R in the second hole 2H and extending to the side wall of the second hole 2H may be formed on a resultant structure of FIG. 14. In other example embodiments, the first insulating liner 128 filling the sacrificial insulating film recess 114R in the second hole 2H and extending to the side wall and the bottom of the second hole 2H may be formed.

In an example embodiment, to form the first insulating liner 128, an insulating film filling the sacrificial insulating film recess 114R in the second hole 2H and conformally covering the side wall and the bottom of the second hole 2H may be formed, and then a portion of the insulating film covering the bottom of the second hole 2H may be removed to form the first insulating liner 128. In some example embodiments, a process of removing the portion of the insulating film covering the bottom of the second hole 2H may be omitted.

The first insulating liner 128 may include the first extending portion 128E conformally covering the side wall of the second hole 2H and the plurality of first protruding portions 128P extending from the first extending portion 128E in the first horizontal direction (X direction) and the second horizontal direction (Y direction). The plurality of first protruding portions 128P may overlap the plurality of sacrificial insulating films 114 in the second horizontal direction (Y direction). Also, the plurality of first protruding portions 128P may be arranged along a side wall of the first extending portion 128E and may be spaced apart from each other in the vertical direction (Z direction) with the first gate insulating film 112 therebetween.

A fourth sacrificial film SFd may be formed in the second hole 2H on which the first insulating liner 128 is formed. The fourth sacrificial film SFd may fill a remaining space of the second hole 2H on which the first insulating liner 128 is formed. Like the first sacrificial film SFa, the second sacrificial film SFb, and the third sacrificial film SFc, the fourth sacrificial film SFd may be formed of or include, but not limited to, a conductive material such as tungsten, a polycrystalline silicon film, or a carbide film.

A third cover insulating film IL3 covering upper surfaces of the second cover insulating film IL2, the first insulating liner 128, and the fourth sacrificial film SFd may be formed on a resultant structure where the fourth sacrificial film SFd is formed. The third cover insulating film IL3 may be formed of or include, but not limited to, a silicon oxide film.

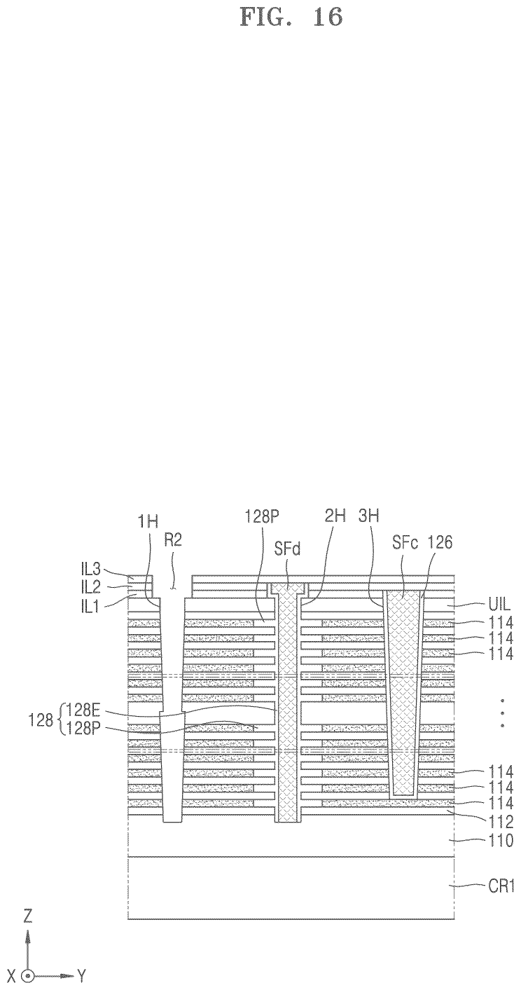

Referring to FIG. 16, a second recess R2 passing through the third cover insulating film IL3, the second cover insulating film IL2, and the first cover insulating film IL1 may be formed on a resultant structure of FIG. 15. The first sacrificial film SFa in the first hole 1H may be exposed from the bottom of the second recess R2. In this case, an upper surface of the third sacrificial film SFc may be covered by the second cover insulating film IL2 without being exposed, and an upper surface of the fourth sacrificial film SFd may be covered by the third cover insulating film IL3 without being exposed.

Next, the first sacrificial film SFa in the first hole 1H may be removed through the second recess R2. As the first sacrificial film SFa is removed, the plurality of sacrificial insulating films 114 may be exposed through a side wall of the first hole 1H. Through the first hole 1H, the plurality of sacrificial insulating films 114 exposed through the side wall of the first hole 1H may be etched. The etching process may be a selective etching process using that the plurality of sacrificial insulating films 114 have a different etch selectivity from the plurality of first gate insulating films 112.

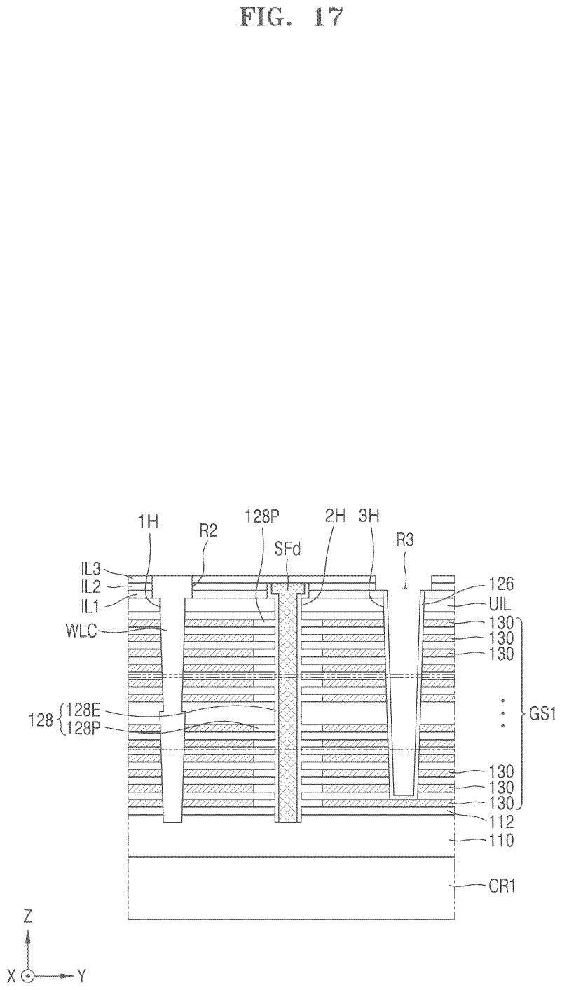

Referring to FIG. 17, the first gate stack GS1 may be formed on a resultant structure of FIG. 16 by forming the plurality of first gate lines 130 in a space where the plurality of sacrificial insulating films 114 (see FIG. 16) are removed.

Next, the word line cut structure WLC filling the inside of the first hole 1H and the second recess R2 may be formed. The word line cut structure WLC may be formed of or include an insulating structure. In some example embodiments, the insulating structure may be formed of silicon oxide, silicon nitride, silicon oxynitride, or a low-k dielectric material. For example, the insulating structure may be formed of a silicon oxide film, a silicon nitride film, a SiON film, a SiOCN film, a SiCN film, or a combination thereof. In other example embodiments, at least a part of the insulating structure may be formed as an air gap. The term “air” used herein may refer to the atmosphere or other gases that may be present during a manufacturing process.

Also, a third recess R3 passing through the third cover insulating film IL3 and the second cover insulating film IL2 may be formed. The third sacrificial film SFc in the third hole 3H may be exposed from the bottom of the third recess R3. In this case, an upper surface of the fourth sacrificial film SFd may be covered by the third cover insulating film IL3 without being exposed.

Next, an etching process for removing the third sacrificial film SFc in the third hole 3H may be performed through the third recess R3. The third sacrificial film SFc may be removed through the etching process and the first gate insulating spacer 126 covering the inner wall of the third hole 3H may be exposed. The etching process may be a selective etching process using that the third sacrificial film SFc and the first gate insulating spacer 126 have different etch selectivities, and after the etching process, the first gate insulating spacer 126 may remain in the third hole 3H.

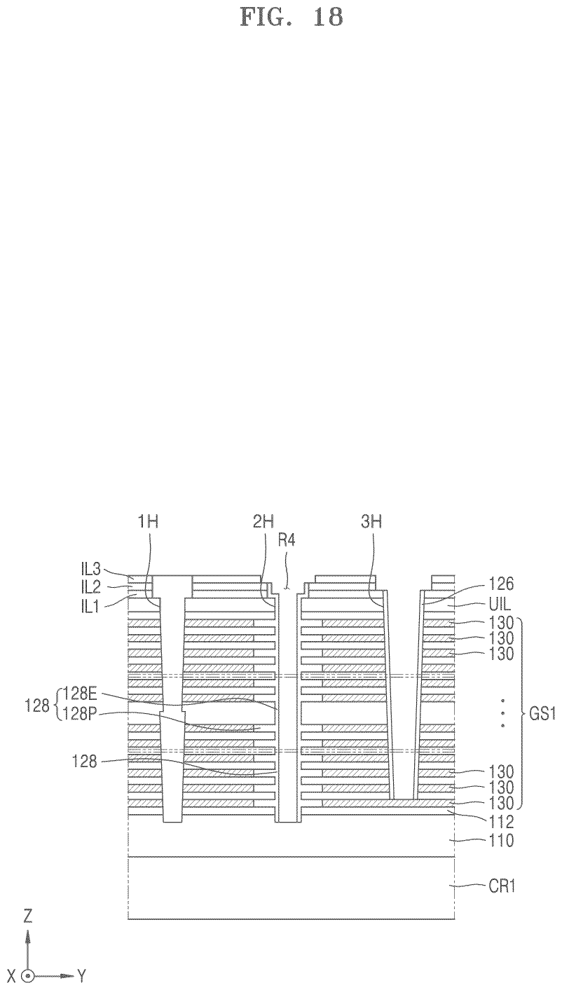

Referring to FIG. 18, an etching process for removing a part of the first gate insulating spacer 126 covering the first gate line 130 of FIG. 17 may be performed. The etching process may be performed as an anisotropic etching process, and may be a dry etching process such as reactive-ion etching (RIE) or plasma etching. Through the etching process, the first gate line 130 may be exposed through the bottom of the third hole 3H. However, even after the etching process, the first gate insulating spacer 126 covering a side wall of the third hole 3H may remain.

Next, a fourth recess R4 passing through the third cover insulating film IL3 may be formed. The fourth sacrificial film SFd in the second hole 2H may be exposed from the bottom of the fourth recess R4. Next, an etching process for removing the fourth sacrificial film SFd in the second hole 2H may be performed through the fourth recess R4. The fourth sacrificial film SFd may be removed through the etching process to expose the first insulating liner 128 covering an inner wall of the second hole 2H. The etching process may be a selective etching process using that the fourth sacrificial film SFd and the first insulating liner 128 have different etch selectivities, and after the etching process, the first insulating liner 128 may remain in the second hole 2H.

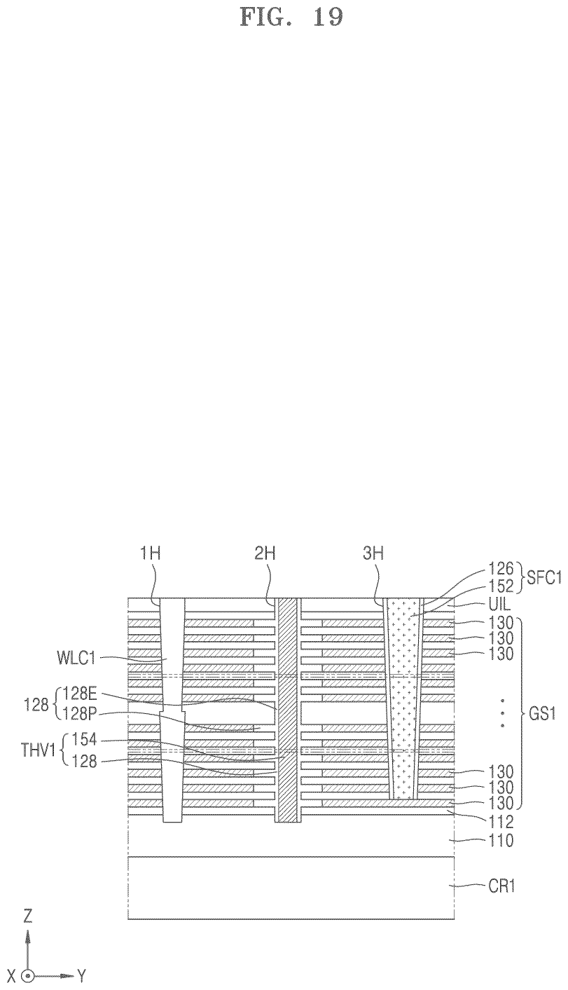

Referring to FIG. 19, after a part of the first gate insulating spacer 126 covering the bottom of the third hole 3H has been removed to expose the first gate line through the bottom of the third contact hole 3H in FIG. 18, the first gate contact plug 152 may be formed by depositing a conductive material in the third hole 3H. Also, the first conductive plug 154 may be formed by depositing a conductive material in the second hole 2H. For example, the conductive material may be deposited by using chemical vapor deposition (CVD), physical vapor deposition (PVD), or atomic layer deposition (ALD). The conductive material may be formed of or include, but not limited to, tungsten, titanium, tantalum, copper, aluminum, titanium nitride, tantalum nitride, tungsten nitride, or a combination thereof.

Next, a chemical mechanical polishing (CMP) process for planarizing an upper surface of a resultant structure where the first gate contact plug 152 and the first conductive plug 154 are formed may be performed. Through the CMP process, the first cover insulating film IL1, the second cover insulating film IL2, and the third cover insulating film IL3 on the upper insulating film UIL may be removed. The first cover insulating film IL1, the second cover insulating film IL2, and the third cover insulating film IL3 may be simultaneously removed, and parts of the first gate contact plug 152 and the first conductive plug 154 overlapping the first cover insulating film IL1, the second cover insulating film IL2, and the third cover insulating film IL3 in the first horizontal direction (X direction) and the second horizontal direction (Y direction) may also be removed. Accordingly, the first through-via THV1 and the first gate line contact SFC1 may be formed.

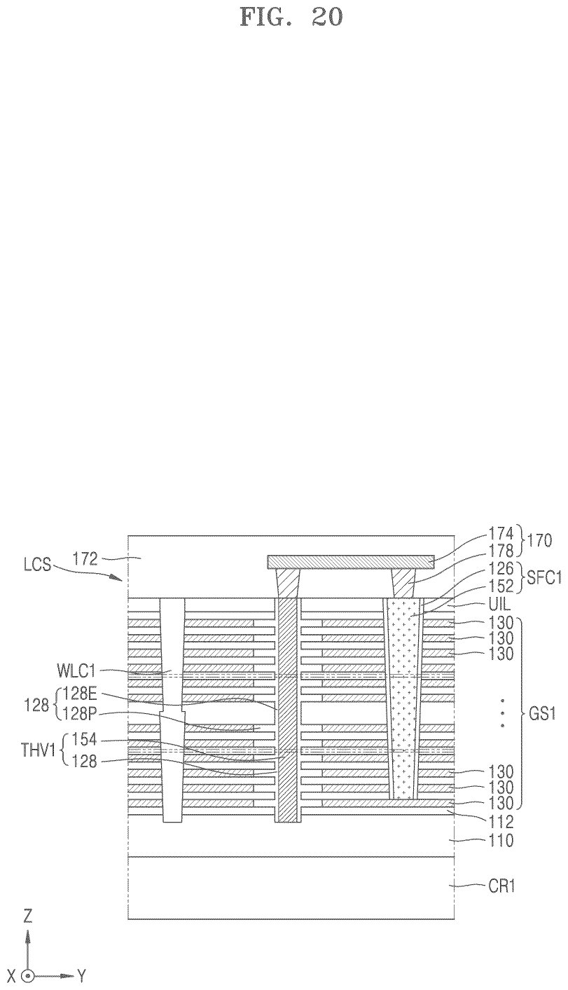

Referring to FIG. 20, a preliminary first upper insulating film P172 may be formed on an upper surface of a resultant structure of FIG. 19, and the plurality of first conductive studs 178 and the first upper wiring layer 174 contacting at least two of the plurality of first conductive studs 178 may be formed. Each of the plurality of first conductive studs 178 may be formed on an upper surface of the first through-via THV1 or an upper surface of the first gate line contact SFC1. The first upper wiring layer 174 may be formed on upper surfaces of the plurality of first conductive studs 178. The preliminary first upper insulating film P172 may be formed to cover surfaces of the plurality of first conductive studs 178 and the first upper wiring layer 174.

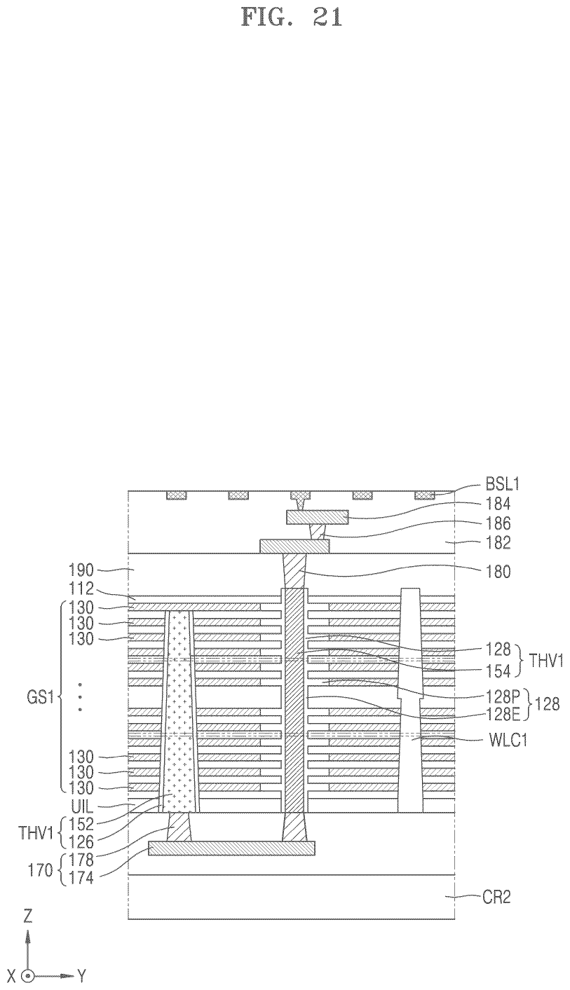

Referring to FIG. 21, a resultant structure of FIG. 20 may be located on a second carrier substrate CR2 so that the plurality of first conductive studs 178 and the first upper wiring layer 174 face an upper surface of the second carrier substrate CR2.

Next, the first substrate 110 (see FIG. 20) of FIG. 20 may be removed, and the first insulating film 190 may be formed in an area where the first substrate 110 (see FIG. 20) is removed. Sequentially, the first through contact 180 passing through the first insulating film 190 to be connected to the first through-via THV1 may be formed, and the first lower insulating film 182, the first lower wiring layer 184, and the first lower contact plug 186 may be formed on the first insulating film 190. The first lower insulating film 182 may be formed to cover surfaces of the first lower wiring layer 184 and the first lower contact plug 186. Next, a plurality of local areas may be removed from an upper surface of the first lower insulating film 182, and a plurality of first bonding metal pads BSL1 may be formed in the plurality of local areas.

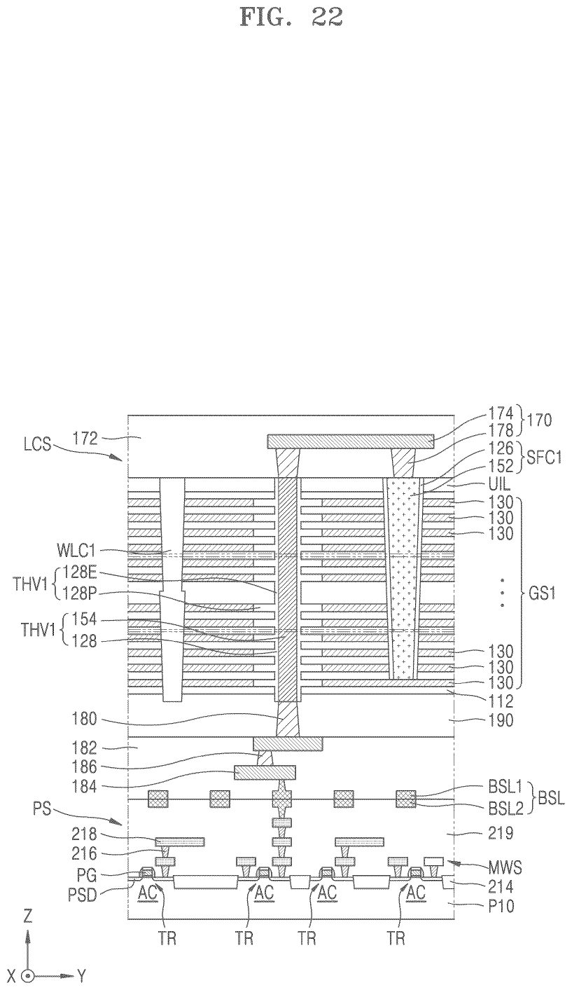

Referring to FIG. 22, a resultant structure of FIG. 21, that is, the lower cell array stack LCS, may be located on the peripheral circuit stack PS so that the plurality of first bonding metal pads BSL1 and a plurality of second bonding metal pads BSL2 of the peripheral circuit stack PS face each other, and the plurality of first bonding metal pads BSL1 and the plurality of second bonding metal pads BSL2 may be bonded to each other. In some example embodiments, the plurality of first bonding metal pads BSL1 and the plurality of second bonding metal pads BSL2 may be directly bonded by pressing the lower cell array stack LCS toward the peripheral circuit stack PS without a separate adhesive layer. In some example embodiments, before the plurality of first bonding metal pads BSL1 and the plurality of second bonding metal pads BSL2 are bonded, a process of surface-treating exposed surfaces of the plurality of first bonding metal pads BSL1 and the plurality of second bonding metal pads B SL2 with hydrogen plasma may be further performed to increase an adhesive force. Each of the plurality of first bonding metal pads BSL1 and the plurality of second bonding metal pads BSL2 may be formed of or include, but not limited to, copper, aluminum, or tungsten.

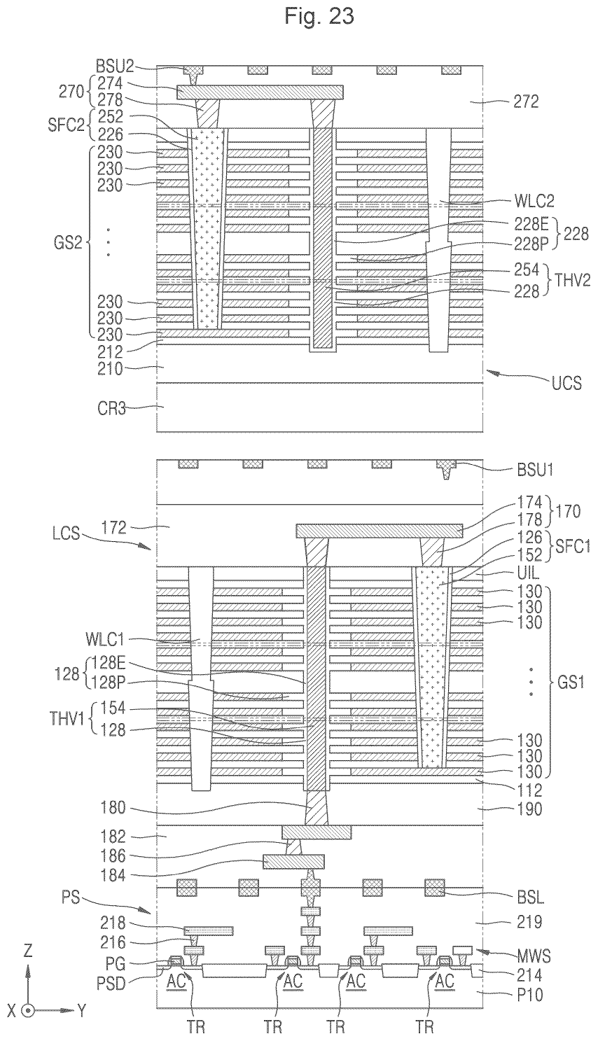

Referring to FIG. 23, a plurality of local areas may be removed from an upper surface of the first upper insulating film 172 on the lower cell array stack LCS, and a plurality of first bonding metal pads BSU1 may be formed in the plurality of local areas.

Independently of a manufacturing process of the lower cell array stack LCS, the upper cell array stack UCS may be formed on a third carrier substrate CR3, in a similar manner to a process of forming the lower cell array stack LCS. Next, a plurality of local areas may be removed from an upper surface of the second lower insulating film 272 of the upper cell array stack UCS, and a plurality of second bonding metal pads BSU2 may be formed in the plurality of local areas.

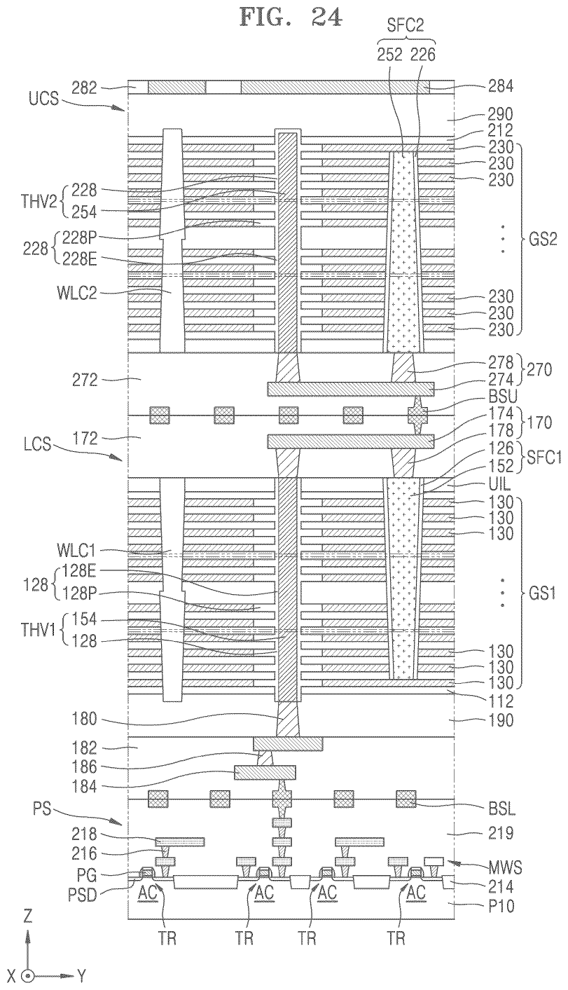

Referring to FIG. 24, the upper cell array stack UCS of FIG. 23 may be located on the lower cell array stack LCS so that the plurality of first bonding metal pads BSU1 and the plurality of second bonding metal pads BSU2 of the upper cell array stack UCS face each other, and the plurality of first bonding metal pads BSU1 and the plurality of second bonding metal pads BSU2 may be bonded to each other. In some example embodiments, the plurality of first bonding metal pads BSU1 and the plurality of second bonding metal pads BSU2 may be directly bonded by pressing the upper cell array stack UCS toward the lower cell array stack LCS, without a separate adhesive layer. In some example embodiments, before the plurality of first bonding metal pads BUS1 and the plurality of second bonding metal pads BSU2 are bonded, a process of surface-treating exposed surfaces of the plurality of first bonding metal pads BSU1 and the plurality of second bonding metal pads BSU2 with hydrogen plasma to increase an adhesive force may be further performed. Each of the plurality of first bonding metal pads BSU1 and the plurality of second bonding metal pads BSU may be formed of or include, but not limited to, copper, aluminum, or tungsten.

Next, a second substrate 210 of FIG. 23 may be removed, and the second insulating film 290 may be formed in an area where the second substrate 210 (see FIG. 23) is removed. The second upper wiring layer 284 may be formed on the second insulating film 290, and the second upper insulating film 282 covering a surface of the second upper wiring layer 284 may be formed.

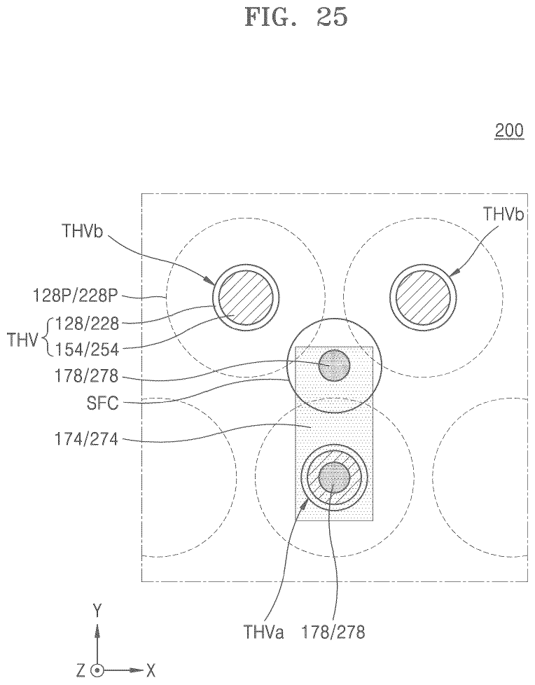

FIG. 25 is a view for describing a memory device 200, according to an example embodiment. FIG. 25 may be a view illustrating an area corresponding to the area “EX1” of FIG. 4.

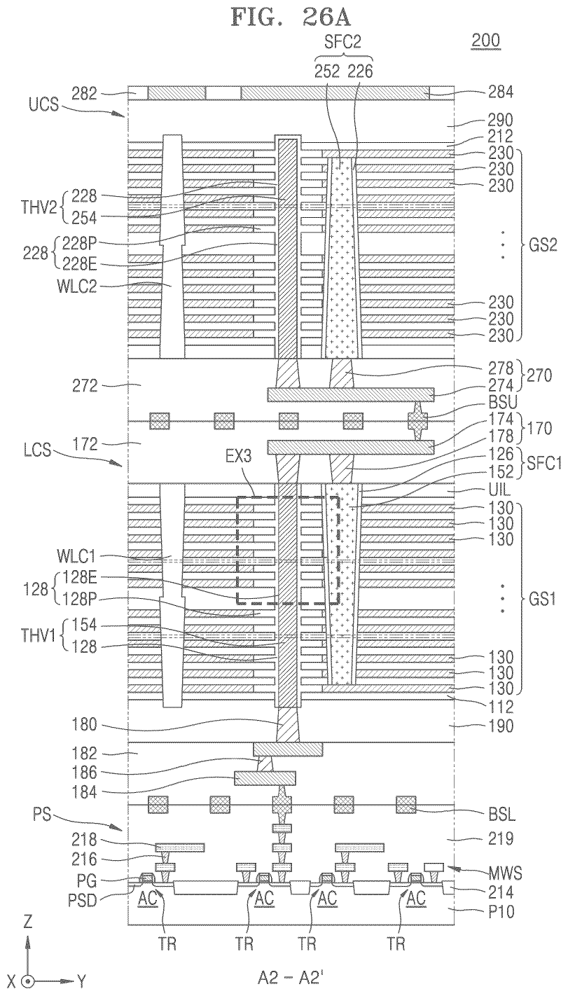

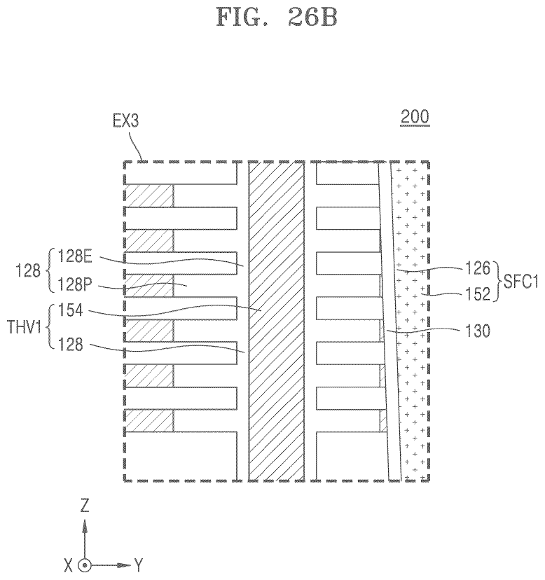

FIG. 26A is a view for describing the memory device 200, according to an example embodiment. FIG. 26A may be a view illustrating an area corresponding to a cross-section taken along line A2-A2′ of FIG. 4. FIG. 26B is a view illustrating an area corresponding to an area “EX3” of FIG. 26A.

The memory device 200 is similar to the memory device 100, and thus, the following will focus on a difference from the memory device 100. The same elements as those in the memory device 100 are denoted by the same reference numerals, and, thus, a repeated description thereof will be omitted.

Referring to FIGS. 25, 26A, and 26B, the memory device 200 may include the peripheral circuit stack PS, and the plurality of cell array stacks CS (e.g., the lower cell array stack LCS and the upper cell array stack UCS) located on the peripheral circuit stack PS to overlap the peripheral circuit stack PS in the vertical direction (Z direction). The plurality of cell array stacks CS may include the memory cell array 20 described with reference to FIG. 1, and the peripheral circuit stack PS may include the peripheral circuit 30 described with reference to FIG. 1.

As shown in FIG. 25, the plurality of gate line contacts SFC and the plurality of through-vias THV adjacent to the plurality of gate line contacts SFC may be located in the extension area EXT of the cell array stack CS described with reference to FIG. 4. The gate line contacts SFC may be spaced apart from each other in the first horizontal direction (X direction), and three through-vias THV arranged around each gate line contact SFC may surround the gate line contact SFC. However, the number of through-vias THV adjacent to each gate line contact SFC is not limited to 3, and may be 1, 2, or 4 or more.

The through-via THV may include the conductive plugs 154/254 and the insulating liners 128/228 surrounding the conductive plugs 154/254. The insulating liners 128/228 may include the extending portions surrounding side walls of the conductive plugs 154/254 and the protruding portions 128P/228P protruding from the extending portions in the first horizontal direction (X direction) and the second horizontal direction (Y direction).

In some example embodiments, as shown in FIG. 25, the protruding portions 128P/228P may overlap a part of the gate line contact SFC in the vertical direction (Z direction).

In detail, as shown in FIGS. 26A and 26b, the plurality of first protruding portions 128P may overlap a part of the first gate line contact SFC1 in the vertical direction (Z direction), and the plurality of second protruding portions 228P may overlap a part of the second gate line contact SFC2 in the vertical direction (Z direction).

As shown in FIGS. 26A and 26B, the plurality of first protruding portions 128P may contact the first gate line contact SFC1 in the horizontal direction (X direction), and the plurality of second protruding portions 228P may contact the second gate line contact SFC2 in the horizontal direction (X direction and Y direction). For example, some of the plurality of first protruding portions 128P may contact the first gate insulating spacer 126 of the first gate line contact SFC1 in the horizontal direction (X direction and Y direction), and some of the plurality of second protruding portions 228P may contact the second gate insulating spacer 226 of the second gate line contact SFC2 in the horizontal direction (X direction and Y direction). Others of the plurality of first protruding portions 128P may be spaced apart from the first gate line contact SFC1 with a part of the first gate line 130 therebetween in the horizontal direction (X direction and Y direction), and others of the plurality of second protruding portions 228P may be spaced apart from the second gate line contact SFC2 with a part of the second gate line 230 therebetween in the horizontal direction (X direction and Y direction). The some of the plurality of first protruding portions 128P contacting the first gate insulating spacer 126 in the horizontal direction (X direction and Y direction) may be located at a higher vertical level than the others of the plurality of first protruding portions 128P spaced apart from the first gate line contact SFC1 with a part of the first gate line 130 therebetween in the horizontal direction (X direction and Y direction). The some of the plurality of second protruding portions 228P contacting the second gate insulating spacer 226 in the horizontal direction (X direction and Y direction) may be located at a lower vertical level than the others of the plurality of second protruding portions 228P spaced apart from the second gate line contact SFC2 with a part of the second gate line 230 therebetween in the horizontal direction (X direction and Y direction).

As described with reference to FIGS. 7A and 7B, at least one of the plurality of first through-vias THV1 and at least one of the plurality of second through-vias THV2 may be electrically connected to the first gate line contact SFC1 and the second gate line contact SFC2, respectively.

In some example embodiments, the at least one first through-via THV1 electrically connected to the first gate line contact SFC1 from among the plurality of first through-vias THV1 may overlap a part of the first gate line contact SFC1 in the vertical direction (Z direction), and the at least one second through-via THV2 electrically connected to the second gate line contact SFC2 from among the plurality of second through-vias THV2 may overlap a part of the second gate line contact SFC2 in the vertical direction (Z direction).

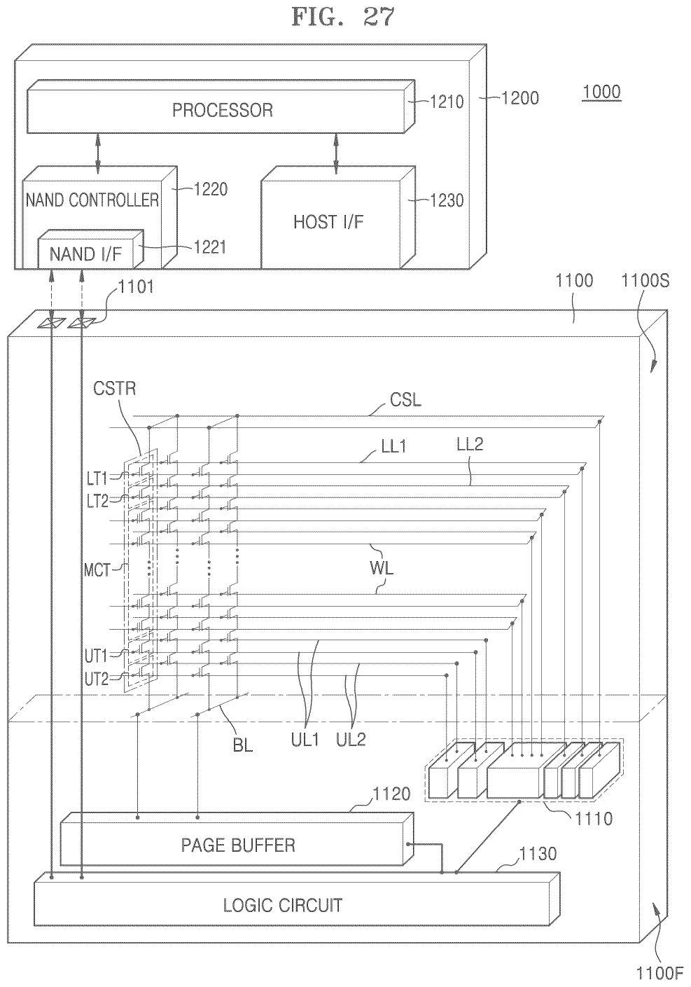

FIG. 27 is a view schematically illustrating a data storage system 1000 including a memory device, according to an example embodiment.

Referring to FIG. 27, the data storage system 1000 may include one or more memory devices 1100 and a memory controller 1200 electrically connected to the memory devices 1100. The data storage system 1000 may be, for example, a solid-state drive (SSD) device, a universal serial bus (USB), a computing system, a medical device, or a computing device including the at least one memory device 1100.

The memory device 1100 may be a nonvolatile semiconductor device, and for example, the memory device 1100 may be a NAND flash semiconductor device including one of the memory devices 10, 100, and 200 described with reference to FIGS. 1, 2, 3A, 3B, 4, 5, 6, 7A, 7B, 8, 25, 26A, and 26B. The memory device 1100 may include a first structure 1100F and a second structure 1100S on the first structure 1100F. The first structure 1100F may be a peripheral circuit structure including a row decoder 1110, a page buffer 1120, and a logic circuit 1130.

The second structure 1100S may be a memory cell structure including a bit line BL, a common source line CSL, a plurality of word lines WL, first and second string selection lines UL1 and UL2, first and second ground selection lines LL1 and LL2, and a plurality of memory cell strings CSTR located between the bit line BL and the common source line CSL.

In the second structure 1100S, each of the plurality of memory cell strings CSTR may include ground selection transistors LT1 and LT2 adjacent to the common source line CSL, string selection transistors UT1 and UT2 adjacent to the bit line BL, and a plurality of memory cell transistors MCT located between the ground selection transistors LT1 and LT2 and the string selection transistors UT1 and UT2. The number of ground selection transistors LT1 and LT2 and the number of string selection transistors UT1 and UT2 may be changed in various ways according to example embodiments.

In some example embodiments, the plurality of ground selection lines LL1 and LL2 may be connected to gate electrodes of the ground selection transistors LT1 and LT2, respectively. The word line WL may be connected to a gate electrode of the memory cell transistor MCT. The plurality of string selection lines UL1 and UL2 may be respectively connected to gate electrodes of the string selection transistors UT1 and UT2.

The common source line CSL, the plurality of ground selection lines LL1 and LL2, the plurality of word lines WL, and the plurality of string selection lines UL1 and UL2 may be connected to the row decoder 1110. The plurality of bit lines BL may be electrically connected to the page buffer 1120.

The memory device 1100 may communicate with the memory controller 1200 through an input/output pad 1101 electrically connected to the logic circuit 1130. The input/output pad 1101 may be electrically connected to the logic circuit 1130.

The memory controller 1200 may include a processor 1210, a NAND controller 1220, and a host interface 1230. In some example embodiments, the data storage system 1000 may include a plurality of memory devices 1100, and in this case, the memory controller 1200 may control the plurality of memory devices 1100.

The processor 1210 may control an overall operation of the data storage system 1000 including the memory controller 1200. The processor 1210 may operate according to certain firmware and may access the memory device 1100 by controlling the NAND controller 1220. The NAND controller 1220 may include a NAND interface 1221 communicating with the memory device 1100. Through the NAND interface 1221, a control command for controlling the memory device 1100, data to be written to the plurality of memory cell transistors MCT of the memory device 1100, and data to be read from the plurality of memory cell transistors MCT of the memory device 1100 may be transmitted. The host interface 1230 may provide a communication function between the data storage system 1000 and an external host. When a control command is received from the external host through the host interface 1230, the processor 1210 may control the memory device 1100 in response to the control command.

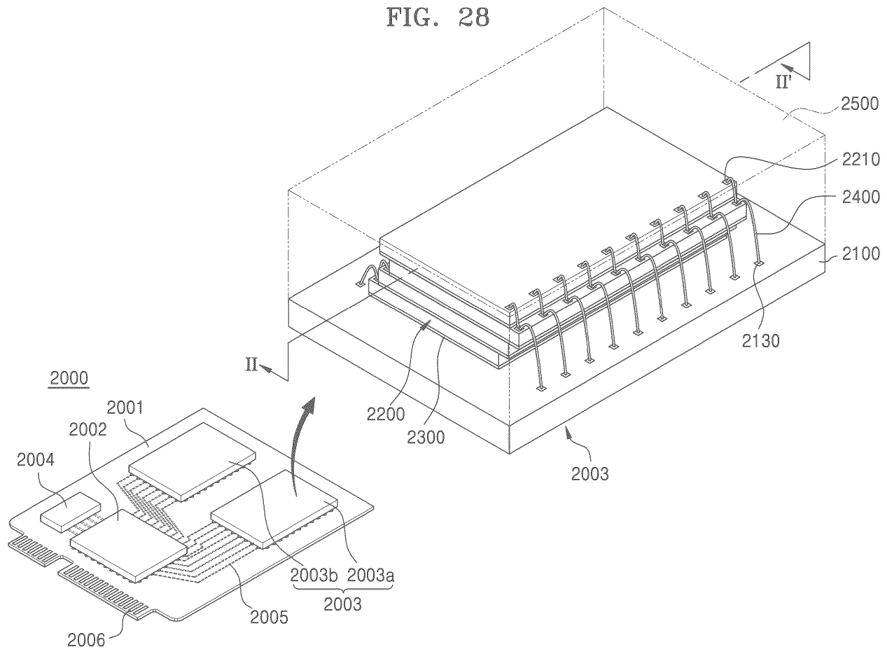

FIG. 28 is a perspective view schematically illustrating a data storage system 2000 including a semiconductor device, according to an example embodiment.

Referring to FIG. 28, the data storage system 2000 according to an example embodiment may include a main substrate 2001, a memory controller 2002 mounted on the main substrate 2001, one or more semiconductor packages 2003, and a dynamic random-access memory (DRAM) 2004. The semiconductor packages 2003 and the DRAM 2004 may be connected to the memory controller 2002 by a plurality of wiring patterns 2005 formed on the main substrate 2001.

The main substrate 2001 may include a connector 2006 including a plurality of pins coupled to the external host. The number and arrangement of pins in the connector 2006 may vary according to a communication interface between the data storage system 2000 and the external host. In some example embodiments, the data storage system 2000 may communicate with the external host according to any one of interfaces such as universal serial bus (USB), peripheral component interconnect express (PCI-Express), serial advanced technology attachment (SATA), and M-Phy for universal flash storage (UFS). In some example embodiments, the data storage system 2000 may operate with power supplied from the external host through the connector 2006. The data storage system 2000 may further include a power management integrated circuit (PMIC) that distributes power received from the external host to the memory controller 2002 and the semiconductor packages 2003.

The memory controller 2002 may write data to the semiconductor packages 2003, may read data from the semiconductor packages 2003, or may increase an operating speed of the data storage system 2000.

The DRAM 2004 may be a buffer memory for reducing a speed difference between the external host and the semiconductor packages 2003 that are data storage spaces. The DRAM 2004 included in the data storage system 2000 may operate as a cache memory and may provide a space for temporarily storing data during a control operation for the semiconductor packages 2003. When the DRAM 2004 is included in the data storage system 2000, the memory controller 2002 may further include a DRAM controller for controlling the DRAM 2004 in addition to a NAND controller for controlling the semiconductor packages 2003.

The semiconductor packages 2003 may include first and second semiconductor packages 2003a and 2003b that are spaced apart from each other. The first and second semiconductor packages 2003a and 2003b may be semiconductor packages each including a plurality of semiconductor chips 2200. Each of the first and second semiconductor packages 2003a and 2003b may include a package substrate 2100, the plurality of semiconductor chips 2200 on the package substrate 2100, an adhesive layer 2300 located on a bottom surface of each of the plurality of semiconductor chips 2200, a connection structure 2400 configured to electrically connect the plurality of semiconductor chips 2200 to the package substrate 2100, and a molding layer 2500 located on the package substrate 2100 to cover the plurality of semiconductor chips 2200 and the connection structure 2400.

The package substrate 2100 may be a printed circuit board including a plurality of package upper pads 2130. Each of the plurality of semiconductor chips 2200 may include an input/output pad 2210. The input/output pad 2210 may correspond to the input/output pad 1101 of FIG. 27. Each of the plurality of semiconductor chips 2200 may include at least one of the memory devices 10, 100, and 200 described with reference to FIGS. 1, 2, 3A, 3B, 4, 5, 6, 7A, 7B, 8, 25, 26A, and 26B.

In some example embodiments, the connection structure 2400 may be a bonding wire configured to electrically connect the input/output pad 2210 to the package upper pad 2130. Accordingly, in the first and second semiconductor packages 2003a and 2003b, the plurality of semiconductor chips 2200 may be electrically connected to each other by using a bonding wire method and may be electrically connected to the package upper pad 2130 of the package substrate 2100. In some example embodiments, in the first and second semiconductor packages 2003a and 2003b, the plurality of semiconductor chips 2200 may be electrically connected to each other by a connection structure including a through silicon via (TSV), instead of the connection structure 2400 using a bonding wire method.

In some example embodiments, the memory controller 2002 and the plurality of semiconductor chips 2200 may be included in one package. In some example embodiments, the memory controller 2002 and the plurality of semiconductor chips 2200 may be mounted on a separate interposer substrate different from the main substrate 2001, and the memory controller 2002 and the plurality of semiconductor chips 2200 may be connected to each other by a wiring formed on the interposer substrate.

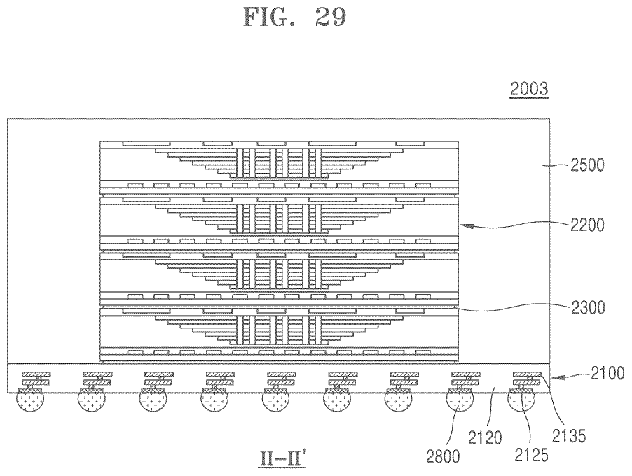

FIG. 29 is a cross-sectional view schematically illustrating semiconductor packages 2003, according to an example embodiment. FIG. 29 is a cross-sectional view taken along line II-II′ of FIG. 28.

Referring to FIG. 29, in the semiconductor package 2003, the package substrate 2100 may be a printed circuit board. The package substrate 2100 may include a package substrate body portion 2120, a plurality of package upper pads 2130 (see FIG. 28) located on an upper surface of the package substrate body portion 2120, a plurality of lower pads 2125 located on or exposed through a bottom surface of the package substrate body portion 2120, and a plurality of internal wirings 2135 configured to electrically connect the plurality of package upper pads 2130 (see FIG. 28) to the plurality of lower pads 2125 inside the package substrate body portion 2120. As shown in FIG. 29, the plurality of package upper pads 2130 may be electrically connected to the plurality of connection structures 2400. As shown in FIG. 29, the plurality of lower pads 2125 may be connected to the plurality of wiring patterns 2005 on the main substrate 2001 of the data storage system 2000 of FIG. 28 through a plurality of conductive bumps 2800. Each of the plurality of semiconductor chips 2200 may include at least one of the memory devices 10, 100, and 200 described with reference to FIGS. 1, 2, 3A, 3B, 4, 5, 6, 7A, 7B, 8, 25, 26A, and 26B.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

As described above, some example embodiments have been illustrated in the drawings and described in the specification. While the example embodiments have been described using specific terms, this is only used for the purpose of explaining the technical idea of the inventive concepts and is not used to limit the meaning and scope of the inventive concepts. Hence, it will be understood by one of ordinary skill in the art that various modifications and other equivalent example embodiments may be made therefrom. Accordingly, the true technical scope of the inventive concepts should be determined by the technical spirit of the appended claims.

While the inventive concepts have been particularly shown and described with reference to some example embodiments thereof, it will be understood that various changes in form and details may be made therein without departing from the spirit and scope of the following claims.

What is claimed is:

1. A memory device comprising:
a peripheral circuit stack comprising a circuit board and a plurality of circuits on the circuit board;
a lower cell array stack comprising a first gate stack on the peripheral circuit stack, the first gate stack comprising a plurality of first gate lines stacked in a vertical direction;
a first vertical channel structure passing through the first gate stack;
a first gate line contact passing through at least a part of the first gate stack, the first gate line contact electrically connected to a first gate line selected from among the plurality of first gate lines;
a plurality of first through-vias spaced apart from the first gate line contact in a horizontal direction and passing through the first gate stack, the plurality of first through-vias connected to corresponding ones of the plurality of circuits of the peripheral circuit stack; and
a first wiring structure configured to electrically connect at least one of the plurality of first through-vias to the first gate line contact,
wherein the plurality of first through-vias comprise
a first vertical interconnect, and a second vertical interconnect, and
wherein the first vertical interconnect is electrically connected to the first gate line contact through the first wiring structure, and
the second vertical interconnect is not electrically connected to the first wiring structure.

2. The memory device of claim 1, wherein the first wiring structure is spaced apart from the peripheral circuit stack with the first gate stack therebetween.

3. The memory device of claim 1, wherein each of the plurality of first through-vias comprises
a conductive plug, and
an insulating liner surrounding a side wall of the conductive plug.

4. The memory device of claim 3, wherein the insulating liner comprises
an extending portion surrounding the side wall of the conductive plug, and
a plurality of protruding portions protruding from the extending portion in the horizontal direction.

5. The memory device of claim 1, wherein the lower cell array stack further comprises a first bit line, the first bit line being between the first vertical channel structure and the peripheral circuit stack and electrically connected to the first vertical channel structure.

6. The memory device of claim 1, wherein the lower cell array stack further comprises a first common source line, the first common source line spaced apart from the peripheral circuit stack with the first vertical channel structure therebetween and configured to supply a common source voltage or a ground voltage to the first vertical channel structure.

7. The memory device of claim 1, wherein the first gate line contact comprises
a gate contact plug, and
a gate insulating spacer surrounding a side wall of the gate contact plug.

8. The memory device of claim 1, wherein the plurality of first gate lines extend parallel to each other in the horizontal direction and overlap each other in the vertical direction.

9. The memory device of claim 1, further comprising:
an upper cell array stack including
a second gate stack on the lower cell array stack, the second gate stack including a plurality of second gate lines stacked in the vertical direction,
a second vertical channel structure passing through the second gate stack,
a second gate line contact passing through at least a part of the second gate stack to be electrically connected to a second gate line selected from among the plurality of second gate lines,
a plurality of second through-vias spaced apart from the second gate line contact in the horizontal direction and passing through the second gate stack, and
a second wiring structure configured to electrically connect at least one of the plurality of second through-vias to the second gate line contact.

10. The memory device of claim 9, wherein
the first wiring structure and the second wiring structure are electrically connected to a same one of the plurality of first through-vias, and
the first wiring structure and the second wiring structure receive a voltage from a same one of the plurality of circuits of the peripheral circuit stack.

11. The memory device of claim 1, further comprising:
a lower bonding structure being between the peripheral circuit stack and the lower cell array stack and bonding the peripheral circuit stack to the lower cell array stack.

12. A memory device comprising:
a peripheral circuit stack comprising a circuit board and a plurality of circuits on the circuit board;
a lower cell array stack comprising a first gate stack on the peripheral circuit stack, the first gate stack comprising a plurality of first gate lines stacked in a vertical direction;
a first vertical channel structure passing through the first gate stack;
a first gate line contact passing through at least a part of the first gate stack and electrically connected to a first gate line selected from among the plurality of first gate lines;
a plurality of first through-vias spaced apart from the first gate line contact in a horizontal direction, the plurality of first through-vias connected to the plurality of circuits of the peripheral circuit stack, respectively, and the plurality of first through-vias partially overlapping a part of the first gate line contact in the vertical direction;
a first wiring structure configured to electrically connect at least one of the plurality of first through-vias to the first gate line contact;
a first bit line overlapping the first vertical channel structure in the vertical direction; and
a first common source line spaced apart from the first bit line in the vertical direction with the first vertical channel structure therebetween.

13. The memory device of claim 12, further comprising:
an upper cell array stack including
a second gate stack on the lower cell array stack, the second gate stack comprising a plurality of second gate lines stacked in the vertical direction,
a second vertical channel structure passing through the second gate stack,
a second gate line contact passing through at least a part of the second gate stack and electrically connected to a second gate line selected from among the plurality of second gate lines,
a plurality of second through-vias passing through the second gate stack, the plurality of second through-vias partially overlapping a part of the second gate line contact in the vertical direction,
a second wiring structure configured to electrically connect at least one of the plurality of second through-vias to the second gate line contact,
a second bit line overlapping the second vertical channel structure in the vertical direction, and
a second common source line spaced apart from the second bit line in the vertical direction with the second vertical channel structure therebetween.

14. The memory device of claim 12, wherein
each of the plurality of first through-vias includes
a conductive plug, and
an insulating liner surrounding a side wall of the conductive plug,
the insulating liner includes
an extending portion surrounding the side wall of the conductive plug, and
a plurality of protruding portions protruding from the extending portion in the horizontal direction, and
the plurality of protruding portions overlap a part of the first gate line contact in the vertical direction.

15. The memory device of claim 14, wherein
the conductive plug includes tungsten, titanium, tantalum, copper, aluminum, titanium nitride, tantalum nitride, tungsten nitride, or a combination thereof, and
the insulating liner includes silicon oxide.

16. The memory device of claim 12, wherein
the first gate line contact comprises
a gate contact plug, and
a gate insulating spacer surrounding a side wall of the gate contact plug,
the gate contact plug includes tungsten, titanium, tantalum, copper, aluminum, titanium nitride, tantalum nitride, tungsten nitride, or a combination thereof, and
the gate insulating spacer includes silicon oxide.

17. The memory device of claim 12, wherein the first wiring structure comprises
a plurality of conductive studs on the first gate line contact and the plurality of first through-vias, respectively, and
a wiring layer on the plurality of conductive studs.

18. A memory device comprising:
a peripheral circuit stack comprising a circuit board and a plurality of circuits on the circuit board;
a lower cell array stack comprising a first gate stack on the peripheral circuit stack, the first gate stack comprising a plurality of first gate lines, the plurality of first gate lines being parallel to each other in a horizontal direction and overlapping each other in a vertical direction,
a first vertical channel structure passing through the first gate stack,
a first gate line contact passing through at least a part of the first gate stack and electrically connected to a first gate line selected from among the plurality of first gate lines,
a plurality of first through-vias spaced apart from the first gate line contact in the horizontal direction, the plurality of first through-vias passing through the first gate stack and connected to corresponding ones of the plurality of circuits of the peripheral circuit stack,
a first wiring structure configured to electrically connect at least one of the plurality of first through-vias to the first gate line contact,
a first bit line between the first vertical channel structure and the peripheral circuit stack, the first bit line electrically connected to the first vertical channel structure, and
a first common source line spaced apart from the peripheral circuit stack with the first vertical channel structure therebetween, the first common source line configured to supply a common source voltage or a ground voltage to the first vertical channel structure; and
an upper cell array stack on the lower cell array stack, the upper cell array stack comprising
a second gate stack comprising a plurality of second gate lines, the plurality of second gate lines being parallel to each other in the horizontal direction and overlapping each other in the vertical direction,
a second vertical channel structure passing through the second gate stack,
a second gate line contact passing through at least a part of the second gate stack and electrically connected to a second gate line selected from among the plurality of second gate lines,
a plurality of second through-vias passing through the second gate stack and spaced apart from the second gate line contact in the horizontal direction,
a second wiring structure configured to electrically connect at least one of the plurality of second through-vias to the second gate line contact,
a second bit line spaced apart from the lower cell array stack with the second vertical channel structure therebetween and electrically connected to the second vertical channel structure, and
a second common source line between the second vertical channel structure and the lower cell array stack, the second common source line configured to supply a common source voltage or a ground voltage to the second vertical channel structure,
wherein each of the plurality of first through-vias and the plurality of second through-vias comprises
a first vertical interconnect, and
a second vertical interconnect, and
wherein the first vertical interconnect from among the plurality of first through-vias is electrically connected to the first gate line contact through the first wiring structure, and the first vertical interconnect from among the plurality of second through-vias is electrically connected to the second gate line contact through the second wiring structure, and
the second vertical interconnect is not electrically connected to any one of the first wiring structure and the second wiring structure.

19. The memory device of claim 18, further comprising:
an upper bonding structure between the lower cell array stack and the upper cell array stack to bond the lower cell array stack to the upper cell array stack; and
a lower bonding structure between the peripheral circuit stack and the lower cell array stack to bond the peripheral circuit stack to the lower cell array stack.

20. The memory device of claim 18, wherein a second gate line, from among the plurality of second gate lines, electrically connected to the second gate line contact is configured to receive a voltage from a corresponding one of the plurality of first gate lines electrically connected to the first gate line contact and from a corresponding one of the plurality of circuits of the peripheral circuit stack.
